(19) United States
(12) Patent Application Publication
(10) Pub. No.: US 2015/0280147 A1
(43) Pub. Date: Oct. 1, 2015

(54) AROMATIC AZA-BICYCLIC COMPOUNDS CONTAINING CU, AG, AU, ZN, AL FOR USE IN ELECTROLUMINESCENT DEVICES

(71) Applicant: MERCK PATENT GMBH, Darmstadt (DE)

(72) Inventors: Lars Wesemann, Tuebingen (DE); Matthias Kleih, Denkendorf (DE); Hermann August Mayer, Tuebingen (DE)

(73) Assignee: Merck Patent GmbH, Darmstadt (DE)

(21) Appl. No.: 14/434,919

(22) PCT Filed: Sep. 13, 2013
(86) PCT No.: PCT/EP2013/002749

§ 371 Date: Apr. 10, 2015

(30) Foreign Application Priority Data
Oct. 13, 2012 (DE) 10 2012 020 167.2

(51) Int. Cl. H01L 51/00; C09K 11/06; C07F 1/08

(52) U.S. Cl. CPC H01L 51/0091; C07F 1/08; C09K 11/06; C09K 2211/188; C09K 2211/1022; C09K 2211/1037; C09K 2211/1011; C09K 2211/1044; C09K 2211/1048; H01L 2251/308; H01L 51/5064

(57) ABSTRACT

The present invention relates to metal complexes and electronic devices, in particular organic electroluminescent devices such as OLEDs, containing said metal complexes. The following compounds of formula (1) are claimed: M(L)ₙ(L′)ₘ, the compound of general formula (1) containing a sub-structure M(L)ₙ of formula (2) and L representing a mono-anionic ligand. Formula (2). The variables are defined as follows: M represents Cu, Ag, Au, Ru, Zn, Al, Ga or In; A represents a co-ordinating group which co-ordinates with M and can be substituted with one or more substituents R; the other variables are defined as cited in the claims.

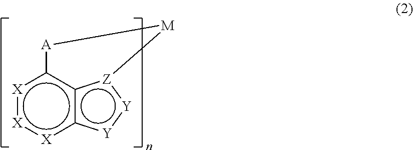

The present invention relates to metal complexes which are suitable for use as emitters in organic electroluminescent devices, and to organic electroluminescent devices which comprise these metal complexes.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are frequently organometallic complexes which exhibit phosphorescence instead of fluorescence (M. A. Baldo et al., Appl. Phys. Lett. 1999, 75, 4-6) or which exhibit singlet harvesting (thermally activated delayed fluorescence) (for example WO 2010/006681). For quantum-mechanical reasons, an up to four-fold energy and power efficiency is possible using compounds of this type as emitters. In general, there is still a need for improvement, in particular with respect to efficiency, operating voltage and lifetime, in the case of OLEDs. This applies, in particular, to OLEDs which emit in the relatively short-wave region, i.e. green and in particular blue.

In accordance with the prior art, use is made, in particular, of iridium and platinum complexes as emitters in phosphorescent OLEDs. In particular for blue emission, however, improvements in these complexes are still desirable. Furthermore, iridium and platinum are rare metals, meaning that it would be desirable, for resource-conserving use, to be able to employ metal complexes based on more widespread metals and to be able to avoid the use of Ir or Pt, and nevertheless to be able to achieve high efficiencies.

WO 2006/061182 discloses iridium and platinum complexes which contain ortho-metallated ligands which form a 6-membered ring chelate with the metal. Complexes with copper, silver, gold, ruthenium or main-group elements are not disclosed.

NOT SUBMITTED ON FILING DATE
X is on each occurrence, identically or differently, CR or N;
Y is on each occurrence, identically or differently, CR or N; or precisely one group Y stands for —CR═CR— or —CR═N—, so that a heteroaromatic six-membered ring forms;
Z is on each occurrence, identically or differently, N, O or S, with the proviso that Z stands for N if a group Y stands for —CR═CR— or —CR═N—;
A is a coordinating group which is coordinated to M and which may be substituted by one or more substituents R;
R is on each occurrence, identically or differently, H, D, F, Cl, Br, I, N(R¹)₂, P(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 20 C atoms or an alkenyl or alkynyl group having 2 to 20 C atoms or a branched or cyclic alkyl, alkoxy or thioalkoxy group having 3 to 20 C atoms, each of which may be substituted by one or more radicals R¹, where one or more non-adjacent CH₂ groups may be replaced by R¹C═CR¹, C≡C, Si(R¹)₂, C═O, NR¹, O, S or CONR¹ and where one or more H atoms may be replaced by D, F, Cl, Br, I or CN, or an aromatic or heteroaromatic ring system having 5 to 60 aromatic ring atoms, which may in each case be substituted by one or more radicals R¹, or an aryloxy or heteroaryloxy group having 5 to 40 aromatic ring atoms, which may be substituted by one or more radicals R¹, or an aralkyl or heteroaralkyl group having 5 to 40 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹; two adjacent radicals R here may also form a mono- or polycyclic, aromatic or aliphatic ring system with one another;
R¹ is on each occurrence, identically or differently, H, D, F, Cl, Br, I, N(R²)₂, P(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 20 C atoms or an alkenyl or alkynyl group having 2 to 20 C atoms or a branched or cyclic alkyl, alkoxy or thioalkoxy group having 3 to 20 C atoms, each of which may be substituted by one or more radicals R², where one or more non-adjacent CH₂ groups may be replaced by R²C═CR², C≡C, Si(R²)₂, C═O, NR², O, S or CONR² and where one or more H atoms may be replaced by D, F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 40 aromatic ring atoms, which may be substituted by one or more radicals R², or an aralkyl or heteroaralkyl group having 5 to 40 aromatic ring atoms, which may be substituted by one or more radicals R², or a diarylamino group, diheteroarylamino group or arylheteroarylamino group having 10 to 40 aromatic ring atoms, which may be substituted by one or more radicals R²; two or more adjacent radicals R² here may form a mono- or polycyclic, aromatic or aliphatic ring system with one another;
R² is on each occurrence, identically or differently, H, D, F or an aliphatic, aromatic and/or heteroaromatic hydrocarbon radical having 1 to 20 C atoms, in which, in addition, one or more H atoms may be replaced by F; two or more substituents R² here may also form a mono- or polycyclic, aromatic or aliphatic ring system with one another;
L′ is, identically or differently on each occurrence, any desired co-ligand or is a coordinating group if L′ is linked to L via V;
n is 1, 2 or 3;
m is 0, 1, 2, 3 or 4;
   one or two substituents R or R¹ on the ligand L here may additionally be bonded to the metal M and thus form a tri- or tetradentate ligand;
   furthermore, the ligand L may be linked to the ligand L′ via one or two bridging units V and thus form a linear tri- or tetradentate ligand.

As described above, L is a monoanionic ligand. In accordance with the invention, however, this only relates to the structure of the ligand drawn in Formula (2), i.e. either the coordinating unit A or the coordinating atom Z is negatively charged. If substituents R and/or R¹ are additionally coordinating to M, these may also be negatively charged, resulting overall in a polyanionic ligand. The same applies if L′ is a coordinating group which is bonded to L via a group V. This may also be negatively charged, resulting overall in a polyanionic ligand.

The indices n and m here are selected so that the coordination number on the metal M in total corresponds to the usual coordination number for this metal. For the metals of the present invention, this is usually the coordination number 2, 3, 4 or 6. It is generally known that metal coordination compounds have different coordination numbers depending on the metal and on the oxidation state of the metal, i.e. bond a different number of ligands. Since the preferred coordination numbers of metals or metal ions in various oxidation states belong to the general expert knowledge of the person skilled in the art in the area of organometallic chemistry or coordination chemistry, it is easy for the person skilled in the art to use a suitable number of ligands, depending on the metal and its oxidation state and depending on the precise structure of the ligand L, and thus to make a suitable choice of the indices n and m.

The circle in the structure of the formula (2) indicates an aromatic or heteroaromatic system, as usual in organic chemistry. Although two circles are drawn-in in this structure for simplification, this nevertheless means, however, that it is a single heteroaromatic system.

An aryl group in the sense of this invention contains 6 to 40 C atoms; a heteroaryl group in the sense of this invention contains 2 to 40 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, phenanthrene, quinoline, isoquinoline, etc.

An aromatic ring system in the sense of this invention contains 6 to 60 C atoms in the ring system. A heteroaromatic ring system in the sense of this invention contains 1 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be interrupted by a non-aromatic unit (preferably less than 10% of the atoms other than H), such as, for example, a C, N or O atom or a carbonyl group. Thus, for example, systems such as 9,9′-spirobifluorene, 9,9-diaryifluorene, triarylamine, diaryl ether, stilbene, etc., are also intended to be taken to be aromatic ring systems in the sense of this invention, as are systems in which two or more aryl groups are interrupted, for example, by a linear or cyclic alkyl group or by a silyl group. Furthermore, systems in which two or more aryl or heteroaryl groups are bonded directly to one another, such as, for example, biphenyl or terphenyl, are likewise intended to be taken to be an aromatic or heteroaromatic ring system.

A cyclic alkyl, alkoxy or thioalkoxy group in the sense of this invention is taken to mean a monocyclic, bicyclic or polycyclic group.

For the purposes of the present invention, a C₁- to C₄₀-alkyl group, in which, in addition, individual H atoms or CH₂ groups may be substituted by the above-mentioned groups, is taken to mean, for example, the radicals methyl, ethyl, n-propyl, i-propyl, cyclopropyl, n-butyl, i-butyl, s-butyl, t-butyl, cyclobutyl, 2-methylbutyl, n-pentyl, s-pentyl, tert-pentyl, 2-pentyl, neopentyl, cyclopentyl, n-hexyl, s-hexyl, tert-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl or 2,2,2-trifluoroethyl. An alkenyl group is taken to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is taken to mean, for example, ethynyl, propynyl, butynyl, pentynyl, hexynyl, heptynyl or octynyl. A C₁- to C₄₀-alkoxy group is taken to mean, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system having 5-60 aromatic ring atoms, which may also in each case be substituted by the radicals R mentioned above and which may be linked to the aromatic or heteroaromatic ring system via any desired positions, is taken to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or transindenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

Preference is given to compounds of the formula (1), characterised in that they are uncharged, i.e. electrically neutral. This is achieved in a simple manner by selecting the charges of the ligands L and L′ so that they compensate for the charge of the complexed metal atom M. As described above, the ligand L is in accordance with the invention monoanionic.

In a preferred embodiment, M is selected from the group consisting of Cu(I), Ag(I), Au(I), Ru(II), Zn(II), Al(III), Ga(III) and In(III), particularly preferably Cu(I) or Zn(II), very particularly preferably Cu(I). The coordination number of Cu(I) here is usually 2 or 4, that of Ag(I) is usually 2, 3 or 4, that of Au(I) is usually 2, that of Ru(II) is usually 6, that of Zn(II) is usually 4 or 6 and that of Al(III), Ga(III) and In(III) is usually 6.

In an embodiment of the invention, M is tricoordinated and the index n=1. In this case, m=1, and a further monodentate ligand L′ is also coordinated to M.

In a further embodiment of the invention, M is a tetracoordinated metal, and the index n stands for 1 or 2. If the index n=1, one bidentate or two monodentate ligands L′, preferably one bidentate ligand L′, are also coordinated to the metal M. If the index n=2, the index m=0.

In a further embodiment of the invention, M is a hexacoordinated metal, and the index n stands for 1, 2 or 3. If the index n=1, two bidentate or four monodentate or one bidentate and two monodentate ligands L′, preferably two bidentate ligands L′, are also coordinated to the metal M. If the index n=2, one bidentate or two monodentate ligands L′, preferably one bidentate ligand L′, are also coordinated to the metal M. If the index n=3, the index m=0.

A corresponding situation applies if L′ is not an independent ligand, but instead is a coordinating group which is bonded to L via a group V.

In a preferred embodiment of the invention, a maximum of one group X stands for N, and the other groups X stand for CR. Particularly preferably, all groups X stand for CR.

In a further preferred embodiment of the invention, a maximum of one group Y stands for N. Particularly preferably, either both groups Y stand for CR, or one group Y stands for CR, and the other group Y stands for —CR═CR—.

Particularly preferably, in total a maximum of one of the groups X or Y stands for N, or all groups X and one group Y stand for CR and the other group Y simultaneously stands for —CR═N—. Very particularly preferably, all groups X and one group Y stand for CR, and the other group Y simultaneously stands for CR or —CR═CR—.

Preferred moieties of the formulae (2) are therefore the moieties of the following formulae (3) to (6),

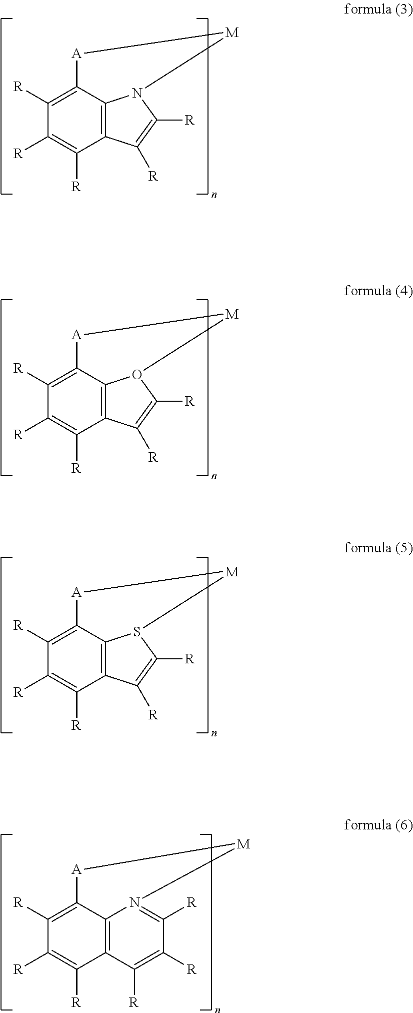

where the symbols and indices used have the meanings given above.

The ligand of the formula (3) is coordinated via a negatively charged nitrogen atom here and in the formula (4), (5) and (6) via a neutral oxygen or sulfur or nitrogen atom. Correspondingly, A in the moiety of the formula (3) is a neutral group which is coordinated to M, while A in the moieties of the formulae (4), (5) and (6) represents a negatively charged group which is coordinated to M.

If radicals R form a ring with one another, structures may arise therefrom as depicted by way of example in the following formulae (3a), (4a), (5a), (6a) and (6b):

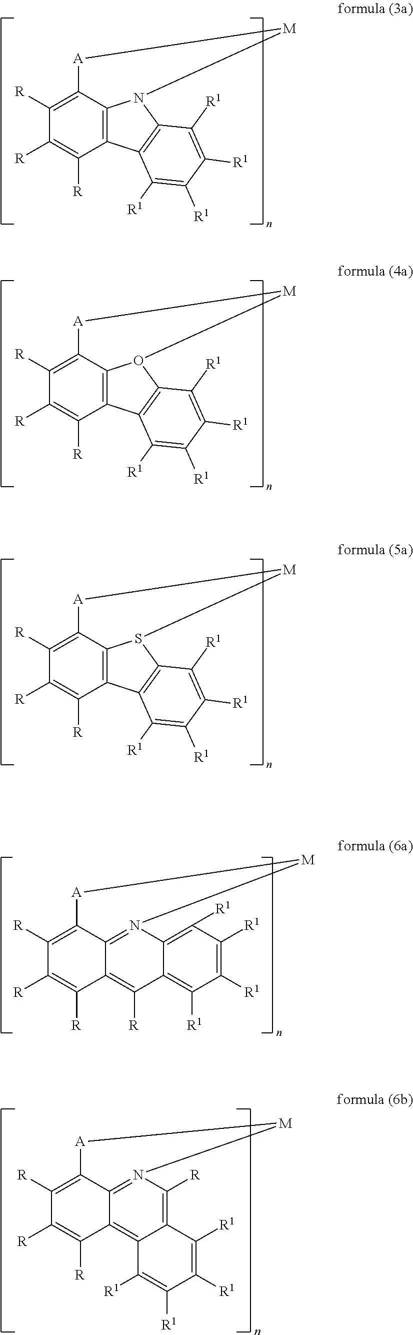

where the symbols and indices used have the meanings given above.

The above-mentioned structures of the formulae (3a) to (6b) only represent the ring formation by way of example. Other ring formations between adjacent radicals R, for example with formation of an aliphatic ring, are possible entirely analogously.

A preferably stands for a heteroaryl group having 5 to 14 aromatic ring atoms which is coordinated to M via a heteroatom and which may be substituted by one or more radicals R. The heteroaryl group particularly preferably has 5 to 10 aromatic ring atoms, very particularly preferably 5 or 6 aromatic ring atoms, and may in each case be substituted by one or more radicals R.

Preferred groups A which are coordinated to M are selected from the structures of the following formulae (7) to (41), where the position denoted by # in each case denotes the bond to the remainder of the ligand L, and the position at which the group is coordinated to M is denoted by *.

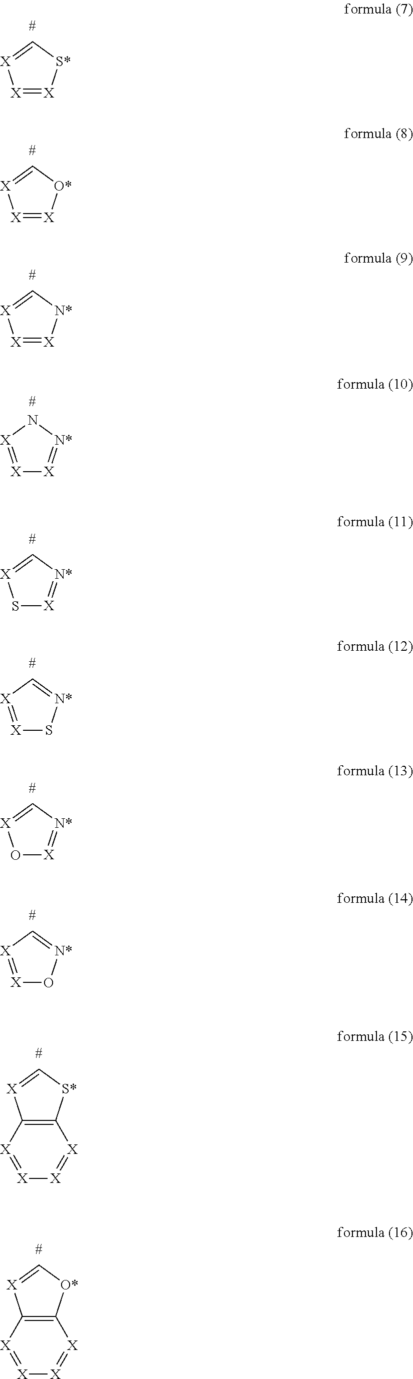

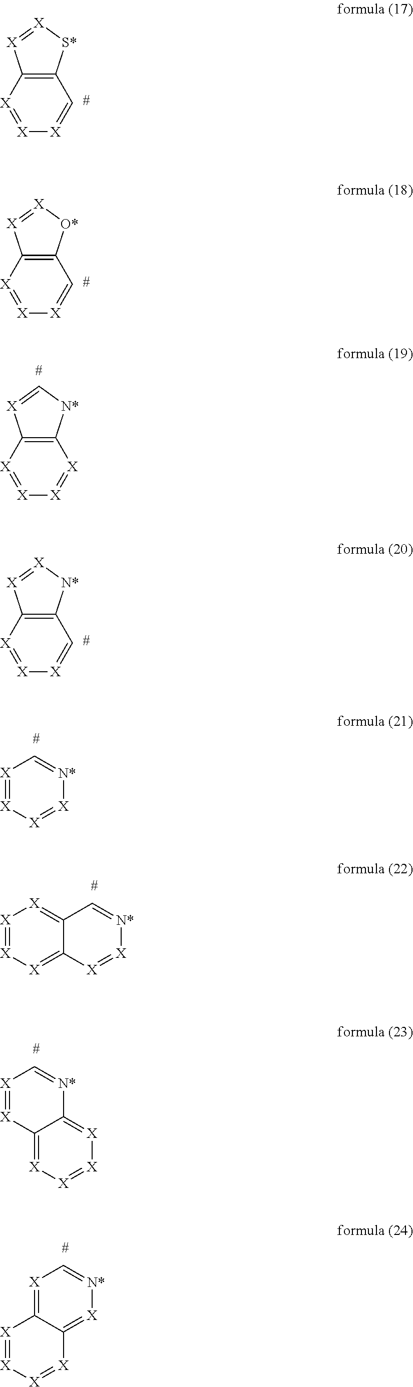

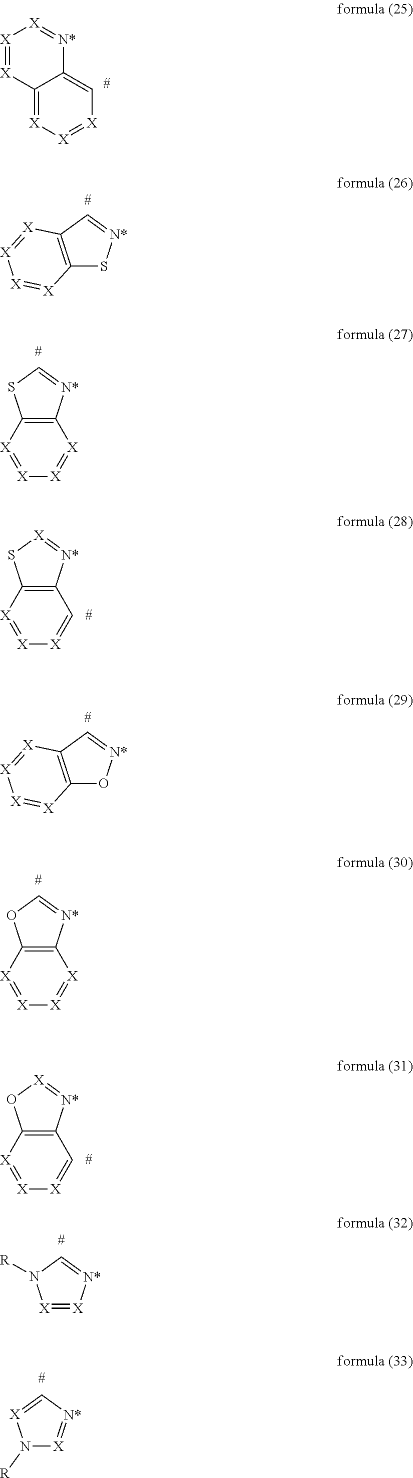

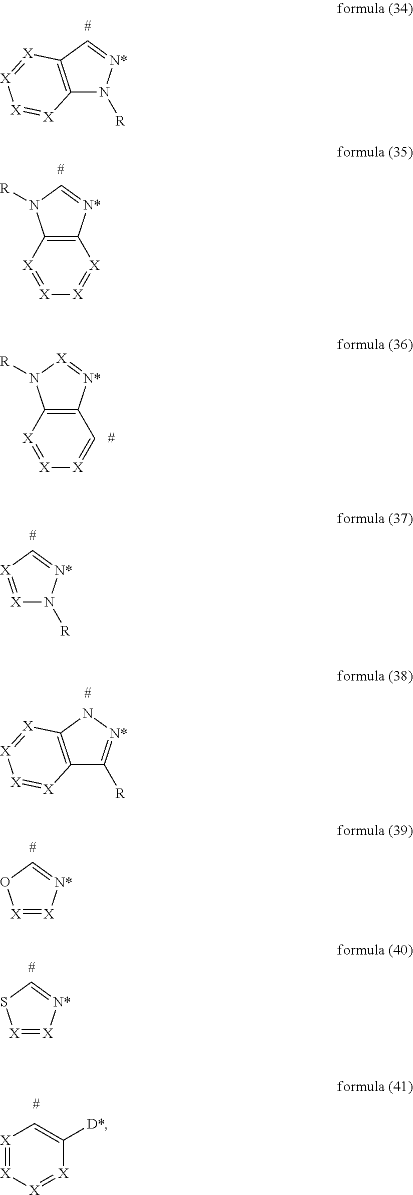

where X and R have the same meaning as described above, and furthermore:
D is O⁻, S⁻, NR⁻, PR⁻, NR₂, PR₂, COO⁻, SO₃, —C(═O)R, —CR(═NR) or —N(═CR₂).

Preferably, a maximum of three symbols X in each group stand for N, particularly preferably a maximum of two symbols X in each group stand for N, very particularly preferably a maximum of one symbol X in each group stands for N. Especially preferably, all symbols X stand for CR.

Further preferred coordinating groups A are carbenes, phosphines, phosphine oxides, phosphine sulfides, amines or imines.

An overview of suitable carbene ligands is revealed by the literature (F. E. Hahn, M. C. Jahnke, Angew. Chem. 2008, 120, 3166-3216). Particularly suitable carbenes are the structures of the following formulae (42) to (44),

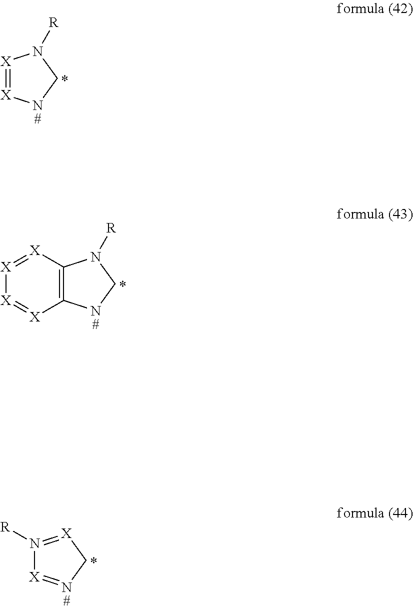

where the symbols used have the meanings given above.

Suitable phosphines, phosphine oxides and phosphine sulfides are the structures of the following formulae (45) to (55),

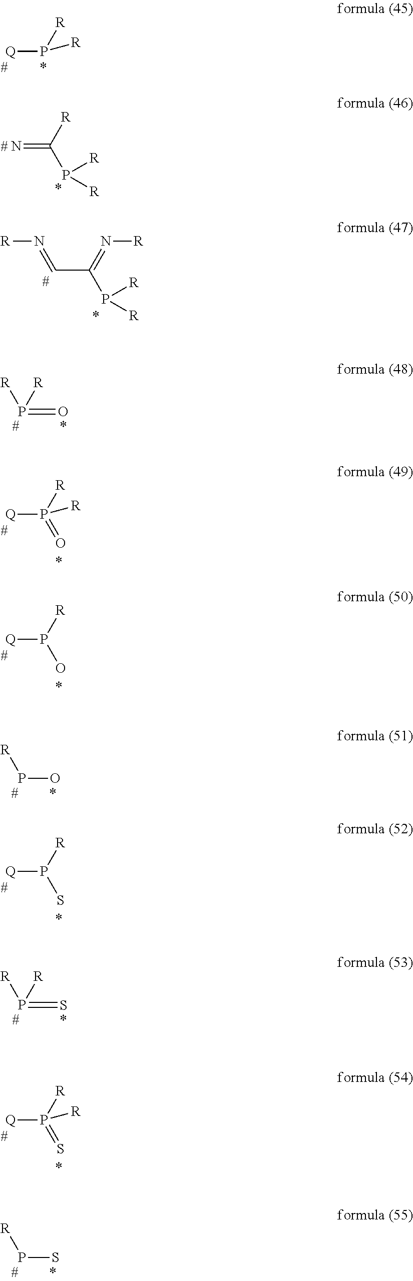

where the symbols used have the meanings given above and Q stands for a divalent group which is selected on each occurrence, identically or differently, from the group consisting of a straight-chain alkylene group having 1 to 8 C atoms or an alkenyl or alkynyl group having 2 to 8 C atoms or a branched or cyclic alkylene group having 3 to 8 C atoms, each of which may be substituted by one or more radicals R¹ and where one or more non-adjacent CH₂ groups may be replaced by R¹C═CR¹, C≡C, Si(R¹)₂, C═O, NR¹, O, S, BR¹ or CONR¹, or a divalent aromatic or heteroaromatic ring system having 5 to 20 aromatic ring atoms, which may in each case be substituted by one or more radicals R¹, or a divalent aryloxy or heteroaryloxy group having 5 to 20 aromatic ring atoms, which may be substituted by one or more radicals R¹, or a divalent aralkyl or heteroaralkyl group having 5 to 20 aromatic ring atoms, which may be substituted by one or more radicals R¹, or a combination of two of the above-mentioned groups.

Preferred groups Q are ortho-linked arylene or heteroarylene groups, which may be substituted by one or more radicals R¹, such as, for example, 1,2-phenylene, 1,2-pyrrole, etc., 2,2′-linked biaryl or biheteroaryl groups, such as, for example, 2,2′-biphenyl, condensed arylene or heteroarylene groups, such as, for example, 1,7-indole, or alkylene groups having 1 to 3 C atoms, in which CH₂ groups may also be replaced by R¹C═CR¹, C═O, NR¹, O or S. These groups may each be substituted by one or more radicals R¹.

Suitable amines and imines are the structures of the following formulae (56) and (57),

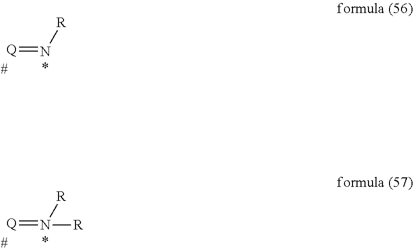

where the symbols used have the meanings given above.

As described above, the ligand L is overall negatively charged. It is therefore preferred if the coordinating group A in the structure of the formula (3) stands for a group of the above-mentioned formulae (7), (8), (10) to (18), (21) to (40) to (49), (53), (54), (56) or (57), if D represents a neutral group. It is furthermore preferred if the coordinating group A in the structure of the above-mentioned formula (4), (5) and (6) stands for a group of the above-mentioned formulae (9), (19), (20), (41), (50) to (52) or (55), if D represents an anionic group.

In a preferred embodiment of the invention, the substituents R are selected on each occurrence, identically or differently, from the group consisting of H, D, F, Br, I, N(R¹)₂, CN, Si(R¹)₃, B(OR¹)₂, C(═O)R¹, a straight-chain alkyl group having 1 to 10 C atoms or an alkenyl group having 2 to 10 C atoms or a branched or cyclic alkyl group having 3 to 10 C atoms, each of which may be substituted by one or more radicals R¹, where one or more H atoms may be replaced by D or F, or an aromatic or heteroaromatic ring system having 5 to 30 aromatic ring atoms, which may in each case be substituted by one or more radicals R¹; two adjacent radicals R here may also form a mono- or polycyclic, aliphatic ring system with one another. These radicals R are particularly preferably selected on each occurrence, identically or differently, from the group consisting of H, D, F, N(R¹)₂, a straight-chain alkyl group having 1 to 6 C atoms or a branched or cyclic alkyl group having 3 to 10 C atoms, where one or more H atoms may be replaced by D or F, or an aromatic or heteroaromatic ring system having 5 to 24 aromatic ring atoms, which may in each case be substituted by one or more radicals R¹; two adjacent radicals R here may also form a mono- or polycyclic, aliphatic or aromatic ring system with one another.

It is furthermore possible for one or two substituents R or R¹ to represent a group which is likewise coordinated or bonded to the metal M. Preferred coordinating groups R are aryl or heteroaryl groups, for example phenyl or pyridyl, aryl or alkyl cyanides, aryl or alkyl isocyanides, amines or amides, alcohols or alcoholates, thioalcohols or thioalcoholates, phosphines, phosphites, carbonyl functions, carboxylates, carbamides or aryl- or alkyl-acetylides.

The moieties ML of the following formulae (58) to (61), for example, are accessible here:

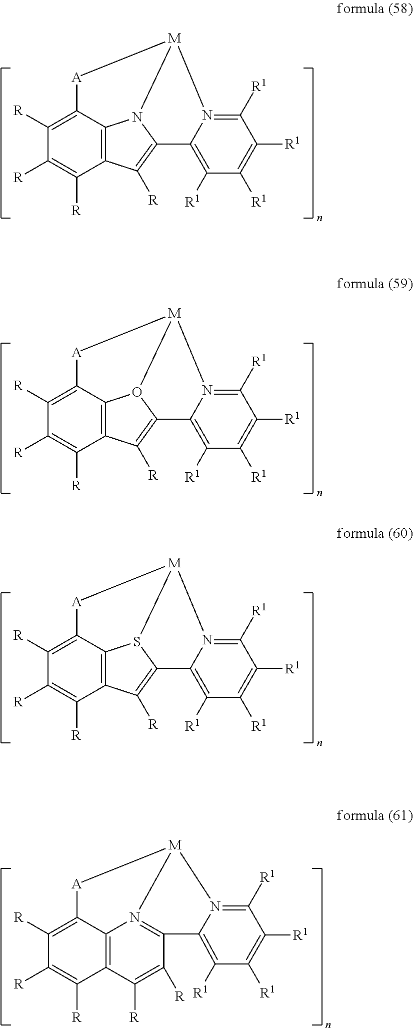

where the symbols and indices used have the same meanings as described above.

The formulae (58) to (61) show by way of example how a substituent R can additionally coordinate to the metal. Other groups R which coordinate to the metal, for example other heteroaryl groups, but also phosphines, amines, etc., are also accessible entirely analogously without exercising further inventive skill. The coordinating group R may likewise be bonded to the group A.

As described above, a bridging unit V which links the ligand L to a further ligand L or L′, so that the ligands overall have a tridentate or tetradentate character, may also be present instead of one of the radicals R. Two bridging units V of this type may also be present. This results in the formation of macrocyclic ligands. In these cases, L′ does not stand for a further ligand, but instead for a coordinating group, where suitable coordinating groups here are the groups of the above-mentioned formulae (7) to (57).

Preferred structures containing polydentate ligands are the metal complexes of the following formulae (62) to (67),

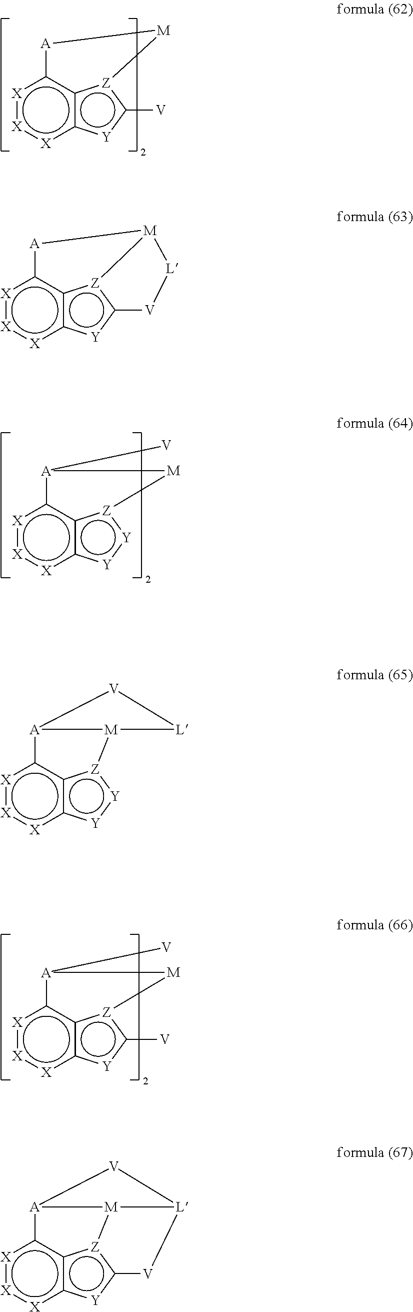

where the symbols used have the meanings given above, where V preferably represents a single bond or a bridging unit containing 1 to 80 atoms from the third, fourth, fifth and/or sixth main group (IUPAC group 13, 14, 15 or 16) or a 3- to 6-membered homo- or heterocycle which covalently bonds the part-ligands L to one another or covalently bonds L to L′. The bridging unit V here may also have an asymmetrical structure, i.e. the linking of V to L and L′ need not be identical. The bridging unit V can be neutral or charged. V is preferably neutral. The charge of V is preferably selected so that overall a neutral complex forms. The preferences indicated above for the moiety MLₙ apply to the ligands, and n is preferably 2.

The precise structure and chemical composition of the group V does not have a significant effect on the electronic properties of the complex since the job of this group is essentially to increase the chemical and thermal stability of the complexes by bridging two ligands L to one another or L to L′.

Suitable groups V are selected, identically or differently on each occurrence, from the group consisting of BR¹, B(R¹)₂, C(R¹)₂, C(═O), Si(R¹)₂, NR¹, PR¹, P(R¹)₂⁺, P(═O)(R²), O, S or a unit of the formula (68) to (77),

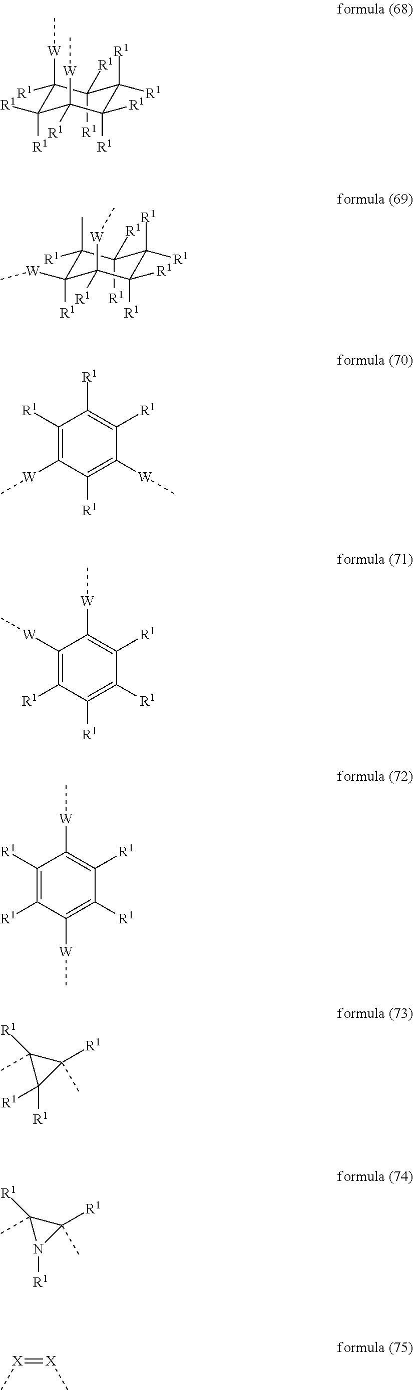

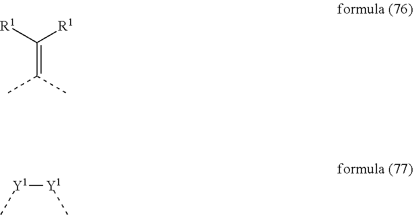

where the dashed bonds in each case indicate the bond to the part-ligands L or L′, W is selected on each occurrence, identically or differently, from the group consisting of C(R¹)₂, BR¹, Si(R¹)₂, NR¹, PR¹, P(═O)R¹, O, S, 1,2-vinylene, which may in each case be substituted by one or more radicals R², and Y¹ stands on each occurrence, identically or differently, for C(R²)₂, N(R²), O or S and the other symbols used each have the meanings indicated above.

Preferred ligands L′ are described below, as occur in formula (1) if they are separate ligands and not coordinating groups which are bonded to L via V.

The ligands L′ are preferably neutral or monoanionic ligands, particularly preferably neutral ligands. They can be monodentate or bidentate and are preferably bidentate, i.e. preferably have two coordination sites. As described above, the ligands L′ can also be bonded to L via a bridging group V.

Preferred neutral, monodentate ligands L′ are selected from the group consisting of carbon monoxide, nitrogen monoxide, alkyl cyanides, such as, for example, acetonitrile, aryl cyanides, such as, for example, benzonitrile, alkyl isocyanides, such as, for example, methyl isonitrile, aryl isocyanides, such as, for example, benzoisonitrile, amines, such as, for example, trimethylamine, triethylamine, morpholine, phosphines, in particular halophosphines, trialkylphosphines, triarylphosphines or alkylarylphosphines, such as, for example, trifluorophosphine, trimethylphosphine, tricyclohexylphosphine, tri-tert-butylphosphine, triphenylphosphine, tris(pentafluorophenyl)phosphine, dimethylphenylphosphine, methyldiphenylphosphine, bis(tert-butyl)phenylphosphine, phosphites, such as, for example, trimethyl phosphite, triethyl phosphite, arsines, such as, for example, trifluoroarsine, trimethylarsine, tricyclohexylarsine, tri-tert-butylarsine, triphenylarsine, tris(pentafluorophenyl)arsine, stibines, such as, for example, trifluorostibine, trimethylstibine, tricyclohexylstibine, tri-tert-butylstibine, triphenylstibine, tris(pentafluorophenyl)stibine, nitrogen-containing heterocycles, such as, for example, pyridine, pyridazine, pyrazine, pyrimidine, triazine, carbenes, in particular Arduengo carbenes, ethers, thioethers and O- or S-containing heteroaromatic compounds, such as, for example, furan, benzofuran, thiophene or benzothiophene.

Preferred monoanionic, monodentate ligands L′ are selected from hydride, deuteride, the halides F⁻, Cl⁻, Br⁻ and I⁻, alkylacetylides, such as, for example, methyl-C≡C⁻, arylacetylides, such as, for example, phenyl-C≡C⁻, cyanide, cyanate, isocyanate, thiocyanate, isothiocyanate, aliphatic or aromatic alcoholates, such as, for example, methanolate, ethanolate, propanolate, isopropanolate, tert-butylate, phenolate, aliphatic or aromatic thioalcoholates, such as, for example, methanethiolate, ethanethiolate, propanethiolate, isopropanethiolate, tert-thiobutylate, thiophenolate, amides, such as, for example, dimethylamide, diethylamide, diisopropylamide, morpholide, carboxylates, such as, for example, acetate, trifluoroacetate, propionate, benzoate, aryl groups, such as, for example, phenyl, naphthyl, and anionic, nitrogen-containing heterocycles, such as pyrrolide, imidazolide, pyrazolide. The alkyl groups in these groups are preferably C₁-C₂₀-alkyl groups, particularly preferably C₁-C₁₀-alkyl groups, very particularly preferably C₁-C₄-alkyl groups. An aryl group is also taken to mean heteroaryl groups. These groups are as defined above.

Preferred neutral or monoanionic, bidentate ligands L′ are selected from diamines, such as, for example, ethylenediamine, N,N,N′,N′-tetramethylethylenediamine, propylenediamine, N,N,N′,N′-tetramethylpropylenediamine, cis- or trans-diaminocyclohexane, cis- or trans-N,N,N′,N′-tetramethyldiaminocyclohexane, imines, such as, for example, 2-[1-(phenylimino)ethyl]pyridine, 2-[1-(2-methylphenylimino)ethyl]pyridine, 2-[1-(2,6-diisopropylphenylimino)ethyl]pyridine, 2-[1-(methylimino)ethyl]pyridine, 2-[1-(ethylimino)ethyl]pyridine, 2-[1-(isopropylimino)ethyl]pyridine, 2-[1-(tert-butylimino)ethyl]pyridine, diimines, such as, for example, 1,2-bis-(methylimino)ethane, 1,2-bis(ethylimino)ethane, 1,2-bis(isopropylimino)-ethane, 1,2-bis(tert-butylimino)ethane, 2,3-bis(methylimino)butane, 2,3-bis-(ethylimino)butane, 2,3-bis(isopropylimino)butane, 2,3-bis(tert-butylimino)-butane, 1,2-bis(phenylimino)ethane, 1,2-bis(2-methylphenylimino)ethane, 1,2-bis(2,6-diisopropylphenylimino)ethane, 1,2-bis(2,6-di-tert-butylphenyl-imino)ethane, 2,3-bis(phenylimino)butane, 2,3-bis(2-methylphenylimino)-butane, 2,3-bis(2,6-diisopropylphenylimino)butane, 2,3-bis(2,6-di-tert-butyl-phenylimino)butane, heterocycles containing two nitrogen atoms, such as, for example, 2,2′-bipyridine, o-phenanthroline, diphosphines, such as, for example, bis(diphenylphosphino)methane, bis(diphenylphosphino)ethane, bis(diphenylphosphino)propane, bis(diphenylphosphino)butane, bis(dimethylphosphino)methane, bis(dimethylphosphino)ethane, bis(dimethylphosphino)propane, bis(diethylphosphino)methane, bis(diethylphosphino)ethane, bis(diethylphosphino)propane, bis(di-tert-butylphosphino)methane, bis(di-tert-butylphosphino)ethane, bis(tert-butylphosphino)propane, 1,3-diketonates derived from 1,3-diketones, such as, for example, acetyl-acetone, benzoylacetone, 1,5-diphenylacetylacetone, dibenzoylmethane, bis(1,1,1-trifluoroacetyl)methane, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, salicyliminates derived from salicylimines, such as, for example, methylsalicylimine, ethylsalicylimine, phenylsalicylimine, dialcoholates derived from dialcohols, such as, for example, ethylene glycol, 1,3-propylene glycol, and dithiolates derived from dithiols, such as, for example, 1,2-ethylenedithiol, 1,3-propylenedithiol.

The ligand L′ is particularly preferably a neutral, bidentate ligand, in particular a diphosphine.

The preferred embodiments indicated above can be combined with one another as desired. In a particularly preferred embodiment of the invention, the preferred embodiments indicated above apply simultaneously.

Examples of metal complexes according to the invention are the structures shown in the following table:

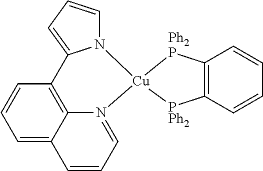

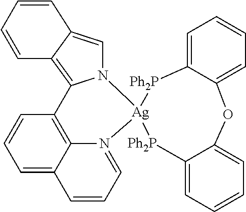

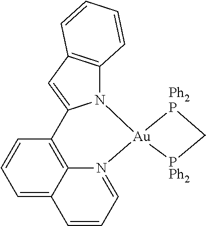

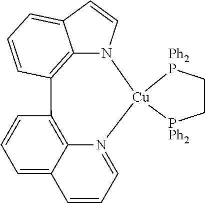

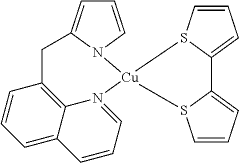

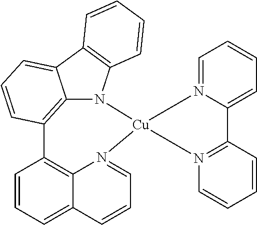

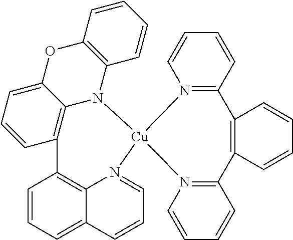

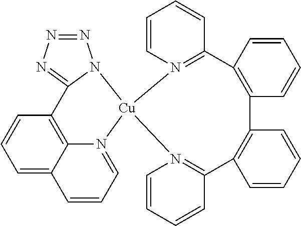

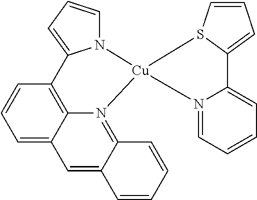

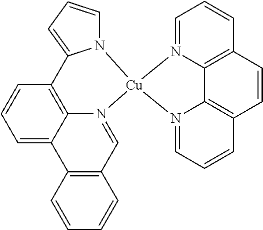

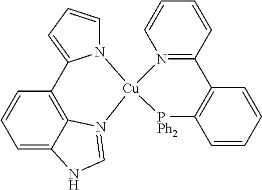

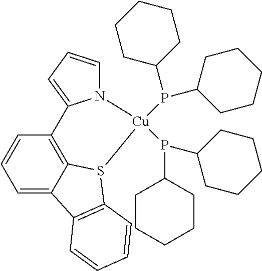

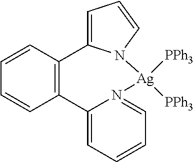

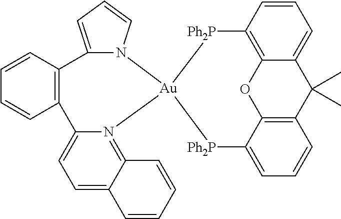

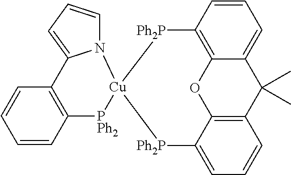

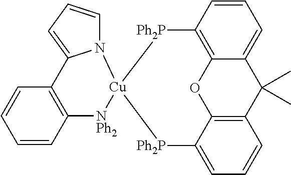

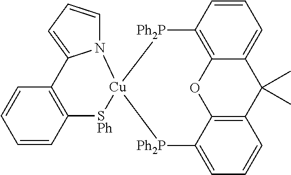

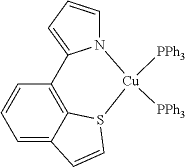

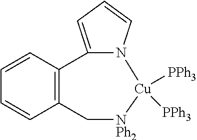

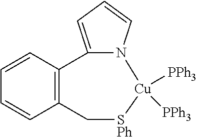

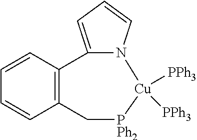

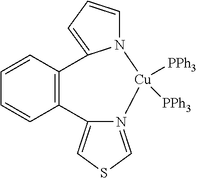

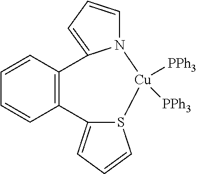

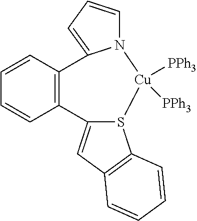

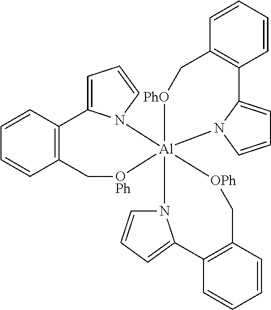

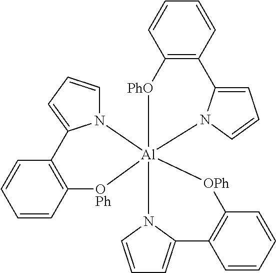

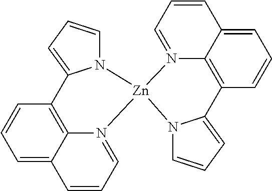

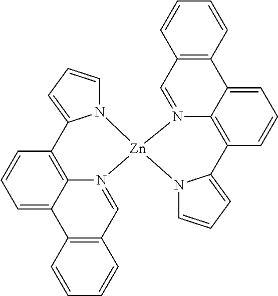

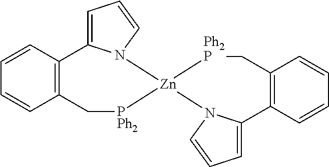

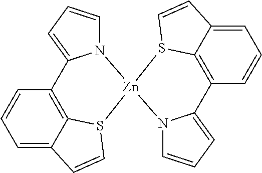

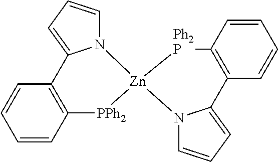

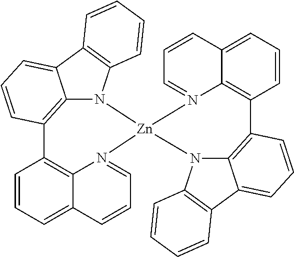

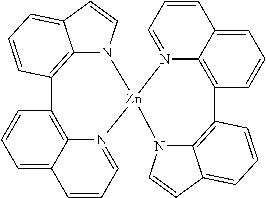

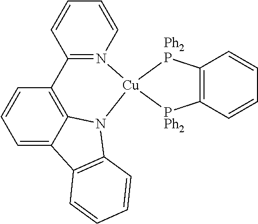

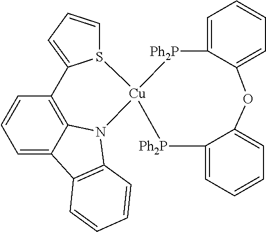

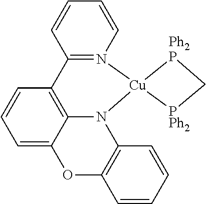

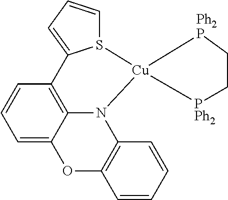

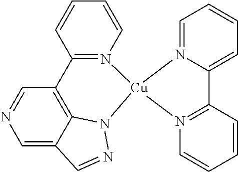

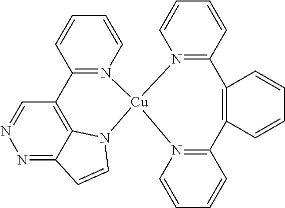

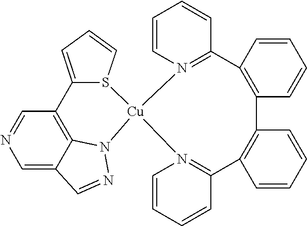

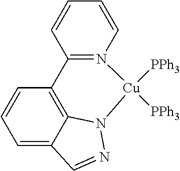

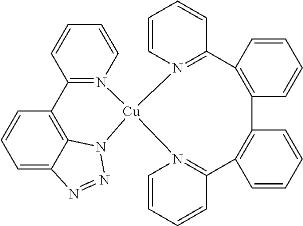

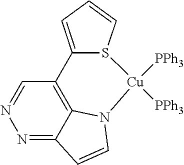

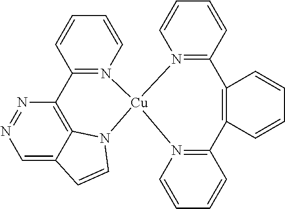

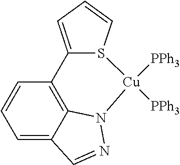

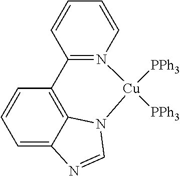

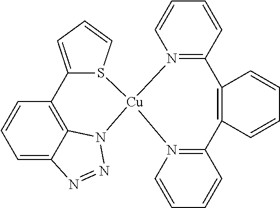

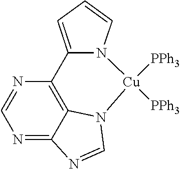

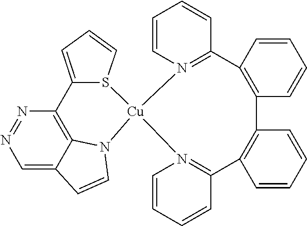

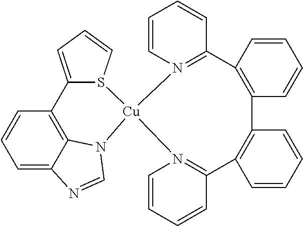

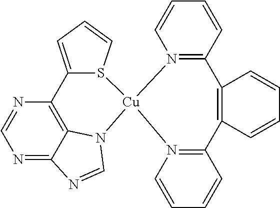

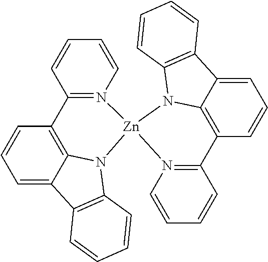

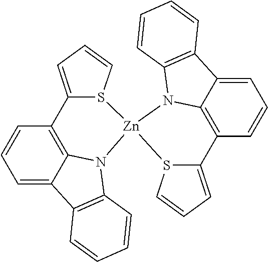

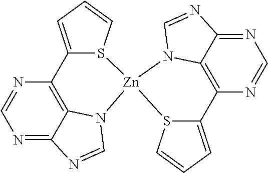

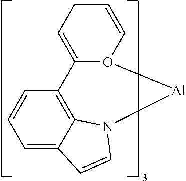

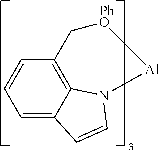

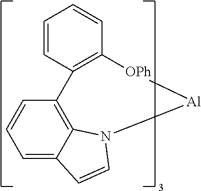

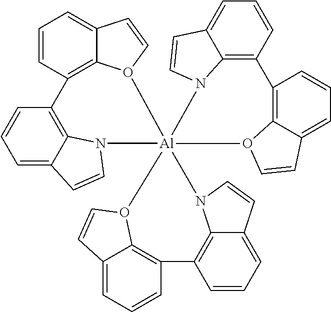

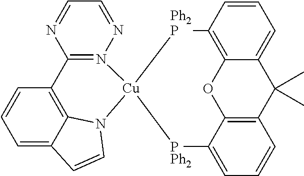

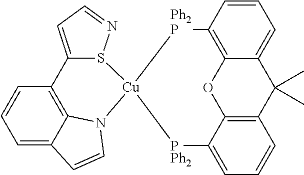

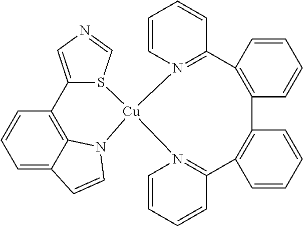

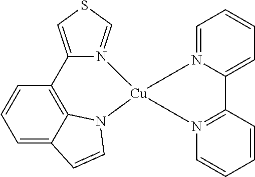

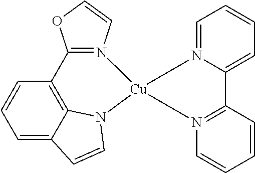

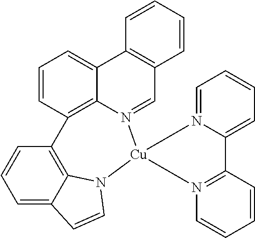

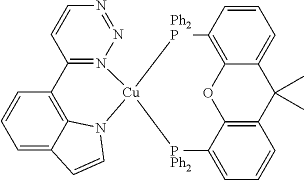

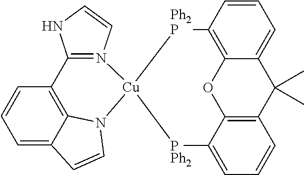

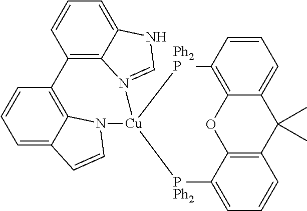

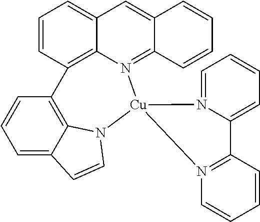

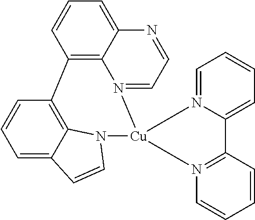

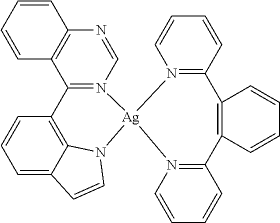

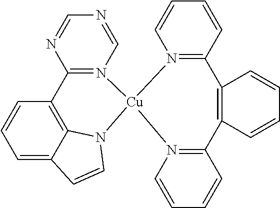

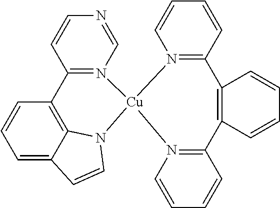

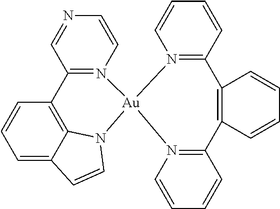

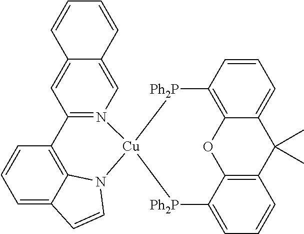

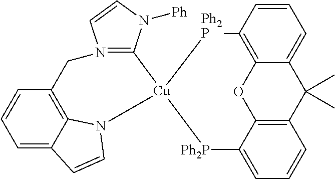

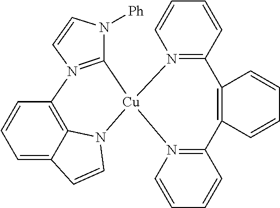

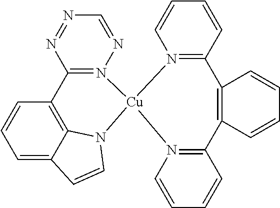

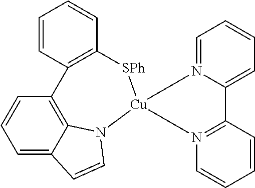

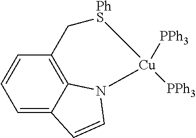

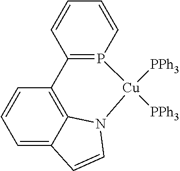

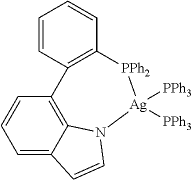

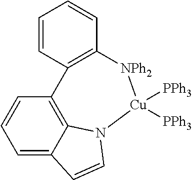

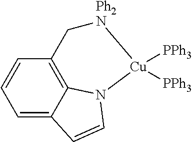

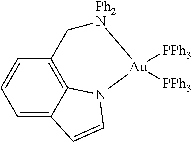

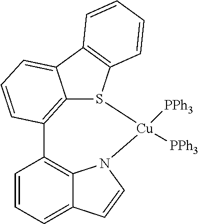

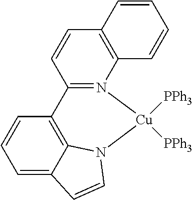

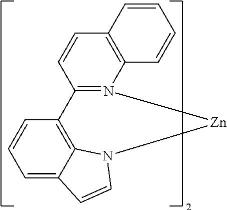

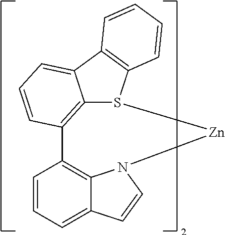

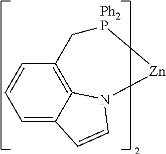

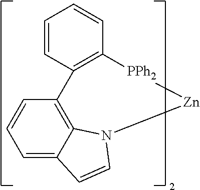

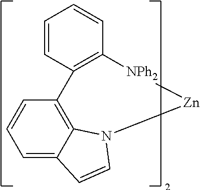

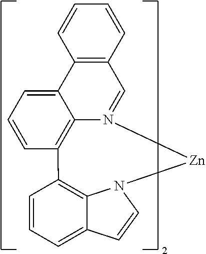

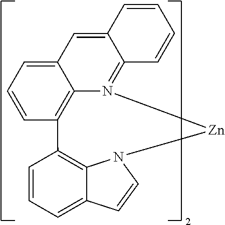

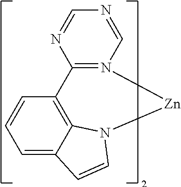

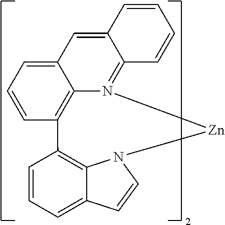

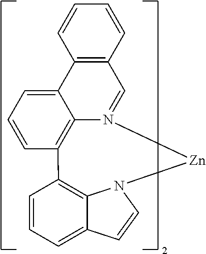

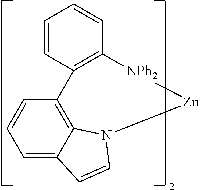

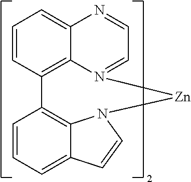

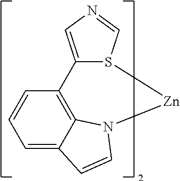

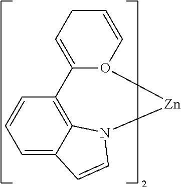

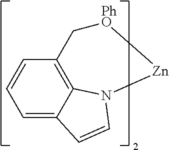

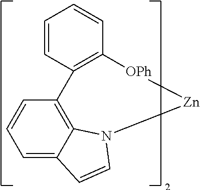

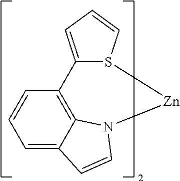

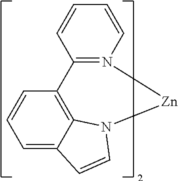

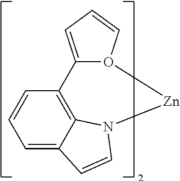

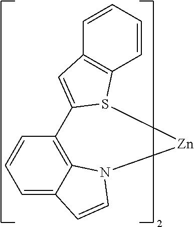

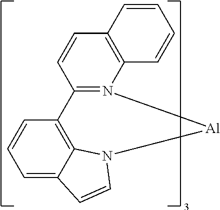

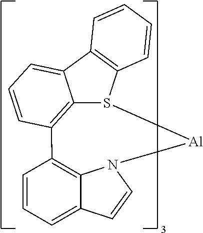

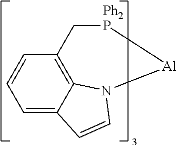

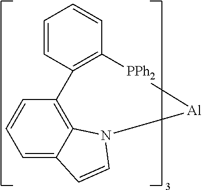

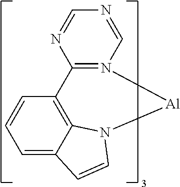

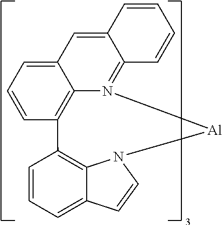

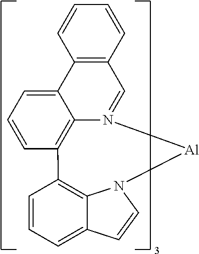

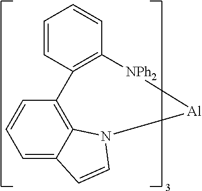

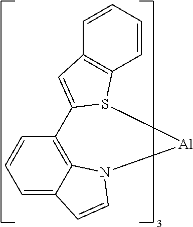

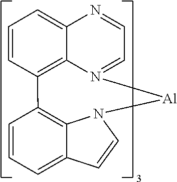

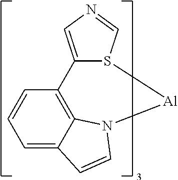

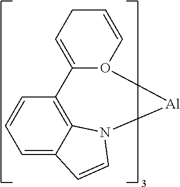

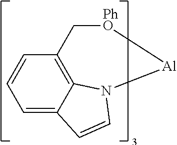

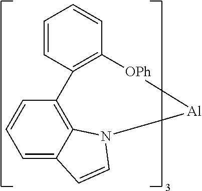

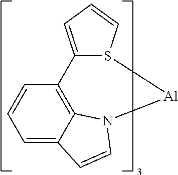

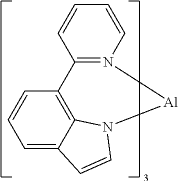

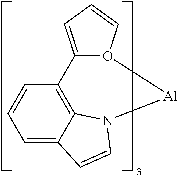

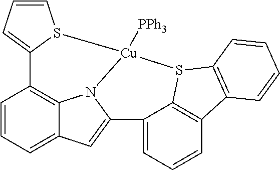

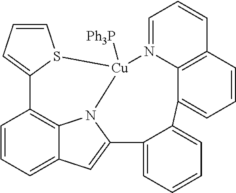

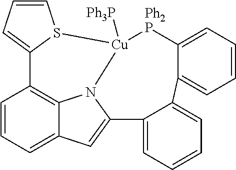

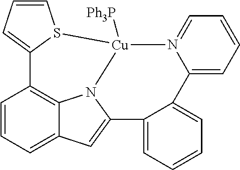

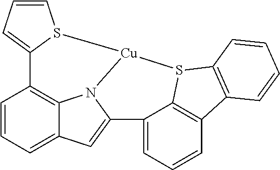

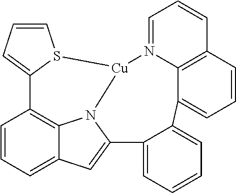

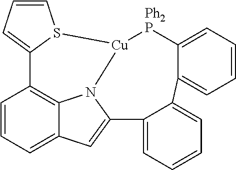

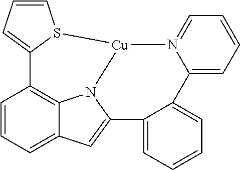

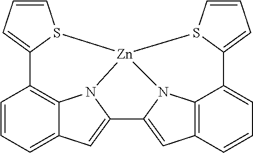

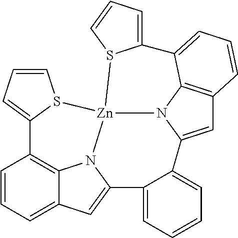

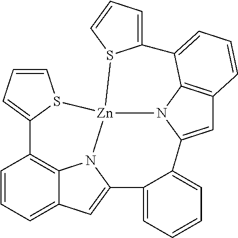

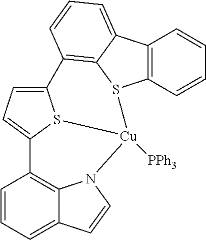

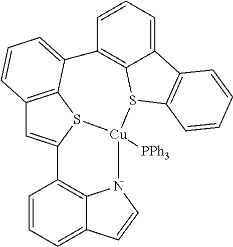

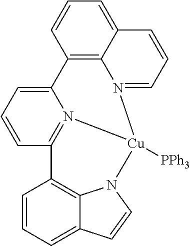

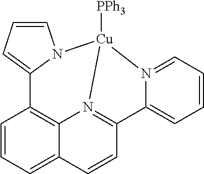

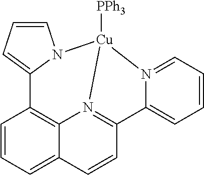

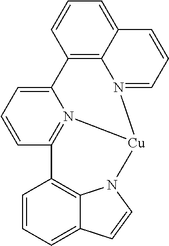

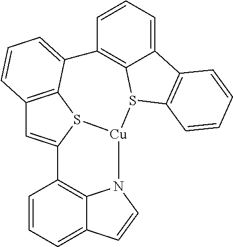

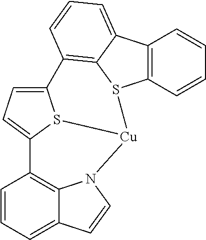

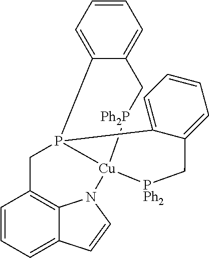

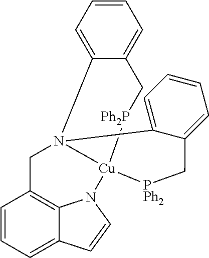

The metal complexes according to the invention can in principle be prepared by various processes. However, the processes described below have proven particularly suitable.

The present invention therefore furthermore relates to a process for the preparation of the compounds of the formula (1) by reaction of the corresponding free ligands L, optionally in deprotonated form, and optionally further ligands L′ with suitable metal salts or metal complexes. The deprotonation reaction of the ligand can either be carried out in situ, for example if a metal salt having a basic anion is employed, or the corresponding anion is already prepared from the ligand before the reaction with the metal by deprotonation.

If the deprotonation of the ligand is to be carried out in situ, use is made, for example, of a metal complex having a basic ligand which, after its deprotonation, preferably has a less-nucleophilic character. Suitable copper starting materials are, for example, mesitylcopper, various copper amides, copper phosphides, copper alkoxides, copper acetate, Cu₂O, etc. Suitable silver starting materials are, for example, mesitylsilver, various silver amides, silver phosphides, silver alkoxides, Ag₂O, etc. Suitable gold starting materials are, for example, mesitylgold, various gold amides, gold phosphides, gold alkoxides, etc. Suitable zinc starting materials are, for example, dimethyl zinc, various zinc amides, zinc phosphides, zinc alkoxides, etc. Suitable aluminium starting materials are, for example, trimethylaluminium, triethylaluminium, various aluminium alkoxides, etc.

If the deprotonation of the ligand is to be carried out before the reaction with the metal M, use is preferably made of an alkali-metal salt having a basic anion which, after its protonation, preferably has a less nucleophilic character and particularly preferably in protonated form is a volatile compound. This produces the corresponding alkali-metal salt of the ligand, which is then reacted with a metal salt (for example [Cu(MeCN)₄][BF₄]) to give the metal complex. Suitable salts for the deprotonation are, for example, sodium tert-butoxide, potassium tert-butoxide, lithium piperidine, bis(trimethylsilyl)amides (for example K[N(SiMe₃)₂]), etc.

The synthesis here can, for example, also be activated thermally, photo-chemically and/or by microwave radiation. The synthesis can likewise be carried out in an autoclave.

These processes, optionally followed by purification, such as, for example, recrystallisation, sublimation or, if necessary, chromatography, enable the compounds of the formula (1) according to the invention to be obtained in high purity, preferably greater than 99% (determined by means of ¹H-NMR and/or HPLC).

The compounds according to the invention can also be rendered soluble by suitable substitution, for example by relatively long alkyl groups (about 4 to 20 C atoms), in particular branched alkyl groups, or optionally substituted aryl groups, for example, xylyl, mesityl or branched terphenyl or quaterphenyl groups. Compounds of this type are then soluble in common organic solvents, such as, for example, toluene or xylene, at room temperature in sufficient concentration to be able to process the complexes from solution. These soluble compounds are particularly suitable for processing from solution, for example by printing processes.

Processing of the compounds according to the invention from the liquid phase, for example by spin coating or by printing processes, requires formulations of the compounds according to the invention. These formulations can be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore furthermore relates to a formulation comprising a compound according to the invention and at least one further compound. The further compound may be, for example, a solvent, in particular one of the above-mentioned solvents or a mixture of these solvents. However, the further compound may also be a further organic or inorganic compound which is likewise employed in the electronic device, for example a matrix material. Suitable matrix materials are indicated below in connection with the organic electroluminescent device. This further compound may also be polymeric.

The complexes of the formula (1) described above or the preferred embodiments indicated above can be used as active component in the electronic device. An electronic device is taken to mean a device which comprises an anode, a cathode and at least one layer, where this layer comprises at least one organic or organometallic compound. The electronic device according to the invention thus comprises an anode, a cathode and at least one layer which comprises at least one compound of the formula (1) given above. Preferred electronic devices here are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) or organic laser diodes (O-lasers), comprising at least one compound of the formula (1) given above in at least one layer. Particular preference is given to organic electroluminescent devices. Active components are generally the organic or inorganic materials which have been introduced between the anode and cathode, for example charge-injection, charge-transport or charge-blocking materials, but in particular emission materials and matrix materials. The compounds according to the invention exhibit particularly good properties as emission material in organic electroluminescent devices. Organic electroluminescent devices are therefore a preferred embodiment of the invention.

The organic electroluminescent device comprises a cathode, an anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers, charge-generation layers and/or organic or inorganic p/n junctions. Interlayers which have, for example, an exciton-blocking function and/or control the charge balance in the electroluminescent device may likewise be introduced between two emitting layers. However, it should be pointed out that each of these layers does not necessarily have to be present.

The organic electroluminescent device here may comprise one emitting layer or a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to three-layer systems, where the three layers exhibit blue, green and orange or red emission (for the basic structure see, for example, WO 2005/011013), or systems which have more than three emitting layers. It may also be a hybrid system, where one or more layers fluoresce and one or more other layers phosphoresce.

In a preferred embodiment of the invention, the organic electroluminescent device comprises the compound of the formula (1) or the preferred embodiments indicated above as emitting compound in one or more emitting layers.

If the compound of the formula (1) is employed as emitting compound in an emitting layer, it is preferably employed in combination with one or more matrix materials. The mixture comprising the compound of the formula (1) and the matrix material comprises between 1 and 99% by vol., preferably between 2 and 90% by vol., particularly preferably between 3 and 40% by vol., especially between 5 and 15% by vol., of the compound of the formula (1), based on the mixture as a whole comprising emitter and matrix material. Correspondingly, the mixture comprises between 99.9 and 1% by vol., preferably between 99 and 10% by vol., particularly preferably between 97 and 60% by vol., in particular between 95 and 85% by vol., of the matrix material, based on the mixture as a whole comprising emitter and matrix material.

The matrix material employed can in general be all materials which are known as matrix materials in the prior art. The triplet level of the matrix material is preferably higher than the triplet level of the emitter. This applies irrespective of the emission mechanism of the compounds according to the invention, i.e. irrespective of whether the compounds exhibit phosphorescence, fluorescence or delayed fluorescence.

Suitable matrix materials for the compounds according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, dibenzofuran derivatives, for example in accordance with WO 2009/148015, or bridged carbazole derivatives, for example in accordance with US 2009/0136779, WO 2010/050778, WO 2011/042107 or WO 2011/088877.

It may also be preferred to employ a plurality of different matrix materials as a mixture, in particular at least one electron-conducting matrix material and at least one hole-conducting matrix material. A preferred combination is, for example, the use of an aromatic ketone, a triazine derivative or a phosphine oxide derivative with a triarylamine derivative or a carbazole derivative as mixed matrix for the metal complex according to the invention. Preference is likewise given to the use of a mixture of a charge-transporting, i.e. a hole- or electron-transporting matrix material and an electrically inert matrix material which is not involved or not essentially involved in charge transport, as described, for example, in WO 2010/108579.

It is furthermore preferred to employ a mixture of a triplet emitter and a compound according to the invention together with a matrix.

A further preferred use form of the compounds according to the invention is as matrix material for emitting compounds, in particular for triplet emitters or for other compounds according to the invention, in an emitting layer. This applies in particular if M stands for Zn.

The compounds according to the invention can also be employed in other functions in the electronic device, for example as hole-transport material in a hole-injection or -transport layer, as charge-generation material or as electron-blocking material.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag, may also be used in addition to the said metals, in which case combinations of the metals, such as, for example, Mg/Ag, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF₂, MgO, NaF, CsF, Cs₂CO₃, etc.). Organic alkali-metal complexes, for example Liq (lithium quinolinate), are likewise suitable for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order either to facilitate irradiation of the organic material (O-SCs) or the coupling-out of light (OLEDs/PLEDs, O-LASERs). Preferred anode materials here are conductive mixed metal oxides. Particular preference is given to indium tin oxide (ITO) or indium zinc oxide (IZO). Preference is furthermore given to conductive, doped organic materials, in particular conductive doped polymers, for example PEDOT, PANI or derivatives of these polymers.

All materials as are used in accordance with the prior art for the layers can generally be used in the further layers, and the person skilled in the art will be able to combine each of these materials with the materials according to the invention in an electronic device without inventive step.

The device is correspondingly structured (depending on the application), provided with contacts and finally hermetically sealed, since the lifetime of such devices is drastically shortened in the presence of water and/or air.

Preference is furthermore given to an organic electroluminescent device, characterised in that one or more layers are coated by means of a sublimation process, in which the materials are vapour-deposited in vacuum sublimation units at an initial pressure of usually less than 10⁻⁵ mbar, preferably less than 10⁻⁶ mbar. It is also possible for the initial pressure to be even lower or even higher, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and thus structured (for example M. S. Arnold et al., Appl. Phys. Left. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing or nozzle printing, but particularly preferably LITI (light induced thermal imaging, thermal transfer printing) or ink-jet printing. Soluble compounds are necessary for this purpose, which are obtained, for example, through suitable substitution.

The organic electroluminescent device may also be produced as a hybrid system by applying one or more layers from solution and applying one or more other layers by vapour deposition. Thus, for example, it is possible to apply an emitting layer comprising a compound of the formula (1) and a matrix material from solution and to apply a hole-blocking layer and/or an electron-transport layer on top by vacuum vapour deposition.

These processes are generally known to the person skilled in the art and can be applied by him without problems to organic electroluminescent devices comprising compounds of the formula (1) or the preferred embodiments indicated above.

The electronic devices according to the invention, in particular organic electroluminescent devices, are distinguished over the prior art by the following surprising advantages:
1. Organic electroluminescent devices comprising compounds of the formula (1) as emitting materials have a very good lifetime.
2. Organic electroluminescent devices comprising compounds of the formula (1) as emitting materials have very good efficiency.
3. The metal complexes according to the invention also give access to organic electroluminescent devices which luminesce in the blue colour region. In particular, blue luminescence with good efficiencies and life-times can only be achieved with great difficulty in accordance with the prior art.
4. The complexes according to the invention can also be achieved, in particular, with copper, which enables the rare metals iridium and platinum to be omitted.

These advantages indicated above are not accompanied by an impairment of the other electronic properties.

The invention is explained in greater detail by the following examples, without wishing to restrict it thereby. The person skilled in the art will be able use the descriptions to produce further compounds according to the invention without inventive step and will thus be able to carry out the invention throughout the range claimed.

### EXAMPLES

The following syntheses are carried out, unless indicated otherwise, in dried solvents under a protective-gas atmosphere. The metal complexes are additionally handled with exclusion of light. The solvents and reagents can be purchased, for example, from Sigma-ALDRICH or ABCR.

### Part 1: Ligand Syntheses

### Example 1

### Synthesis of the Ligand 7-BTpln

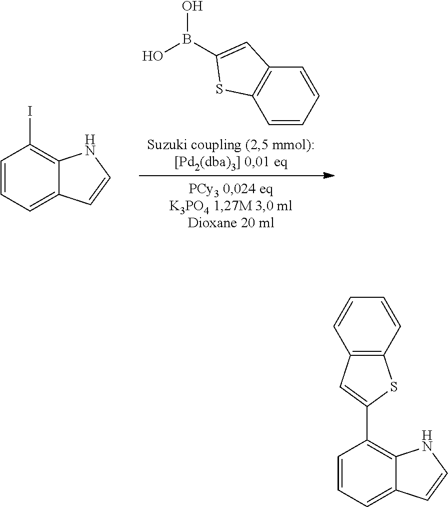 [SMILES: Ic1cccc2cc[nH]c12 ; OB(O)c1cc2ccccc2s1 ; c1ccc2sc(-c3cccc4cc[nH]c34)cc2c1]

446.5 mg of benzo[b]thiophen-2-ylboronic acid (2.51 mmol), 554.2 mg of 7-iodoindole (2.28 mmol), 20.9 mg of [Pd₂(dba)₃] (0.023 mmol) and 15.3 mg of PCy₃ (0.055 mmol) are weighed out into a 70 ml autoclave, blanketed with inert gas, 20 ml of dioxane are added, and 3.05 ml of 1.27 M K₃PO₄ soln. are added dropwise. The autoclave is sealed, and the contents are stirred at 100° C. for 24 h. The reaction mixture is taken up in 30 ml of dichloromethane and washed 3× with H₂O, the aqueous phase is then extracted 3× with 30 ml of dichloromethane each time, the organic phase is dried over MgSO₄, filtered off and concentrated in vacuo. The product is isolated with the aid of a silica-gel column (dichloromethane:hexane) 3:7, R_{f}=0.25). Yield 84%.

¹H NMR (DCM-d₂, 400.13 MHz): δ 8.73-8.92 (m, 1H), 7.92-7.96 (m, 1H), 7.87-7.90 (m, 1H), 7.72-7.75 (m, 1H), 7.61 (s, 1H), 7.49-7.53 (m, 1H), 7.44-7.49 (m, 1H), 7.39-7.44 (m, 1H), 7.29-7.31 (m, 1H), 7.23-7.28 (m, 1H), 6.68-6.71 (m, 1H).

¹³C NMR (DCM-d₂, 100.13 MHz): δ 142.09, 141.07, 139.86, 133.79, 129.38, 125.49, 125.28, 124.96, 124.06, 122.76, 122.72, 121.77, 121.49, 120.72, 118.83, 103.72.

### Example 2

### Synthesis of the Ligand 7-Fuln

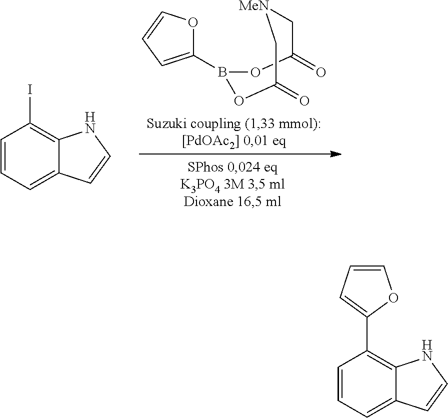 [SMILES: Ic1cccc2cc[nH]c12 ; CN1CC(=O)OB(c2ccco2)OC(=O)C1 ; c1coc(-c2cccc3cc[nH]c23)c1]

297.7 mg of 2-(furan-2-yl)-6-methyl-1,3,6,2-dioxazaborolane-4,8-dione (1.33 mmol), 324.1 mg of 7-iodoindole (1.33 mmol), 15 mg of Pd(OAc)₂ (0.066 mmol) and 54.7 mg of SPhos (0.133 mmol) are weighed out into a 30 ml glass vessel, blanketed with inert gas, 16.5 ml of dioxane are added, and 3.5 ml of 3 M K₃PO₄ solution are added dropwise. The autoclave is sealed, and the contents are stirred vigorously at 100° C. for 2 h. The reaction mixture is taken up in 30 ml of dichloromethane, washed 2× with H₂O and 1× with concentrated NaCl solution, the aqueous phase is then extracted 3× with 30 ml of dichloromethane each time, the organic phase is dried over MgSO₄, filtered off and concentration in vacuo. The product is isolated with the aid of a silica-gel column (dichloromethane:hexane 3:7, R_{f}=0.31). Yield 64%.

¹H NMR (DCM-d₂, 400.13 MHz): δ 9.40 (bs, W_{1/2}=27.87 Hz, 1H), 7.65 (d, ³J_{HH}=1.79 Hz, 1H), 7.62 (d, ³J_{HH}=7.86 Hz, 1H), 7.49 (dd, ³J_{HH}=7.45 Hz, ³J_{HH}=0.88 Hz, 1H), 7.34 (t, ³J_{HH}=2.80 Hz, 1H), 7.17 (t, ³J_{HH}=7.59 Hz, 1H), 6.83 (d, ³J_{HH}=3.44 Hz, 1H), 6.60-6.63 (m, 2H).

¹³C NMR (DCM-d₂, 100.13 MHz): δ 154.77, 142.14, 131.97, 129.69, 125.40, 120.89, 120.34, 118.27, 115.08, 112.23, 105.61, 102.93.

### Example 3

### Synthesis of the Ligand 7-Pyln

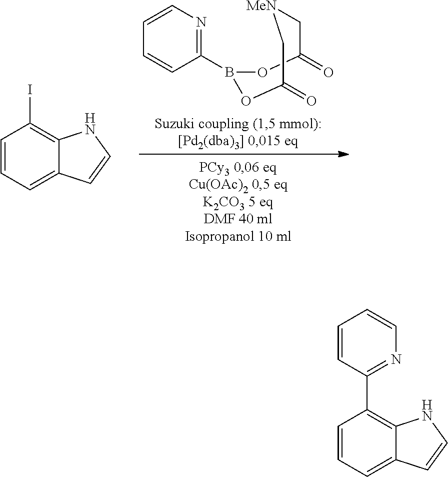 [SMILES: Ic1cccc2cc[nH]c12 ; CN1CC(=O)OB(c2ccccn2)OC(=O)C1 ; c1ccc(-c2cccc3cc[nH]c23)nc1]

351.0 mg of 6-methyl-2-(pyridin-2-yl)-1,3,6,2-dioxazaborocane-4,8-dione (1.5 mmol), 243.0 mg of 7-iodoindole (1 mmol), 13.7 mg of [Pd₂(dba)₃] (0.015 mmol), 16.8 mg of PCy₃ (0.06 mmol), 90.8 mg of Cu(OAc)₂ and 691 mg of K₂CO₃ are weighed out into a 70 ml autoclave, blanketed with an inert gas, 40 ml of N,N-dimethylmethanamide and 10 ml of isopropanol are added. The autoclave is sealed, and the contents are stirred at 100° C. for 24 h. The reaction mixture is taken up in 30 ml of dichloromethane and washed 3× with H₂O, the aqueous phase is then extracted 3× with 30 ml of dichloromethane each time, the organic phase is dried over MgSO₄, filtered off and concentrated in vacuo. The product is isolated with the aid of a silica-gel column (dichloromethane:hexane 4:6, R_{f}=0.56). Yield 76%.

### Example 4

### Synthesis of the Ligand 7-Tpln

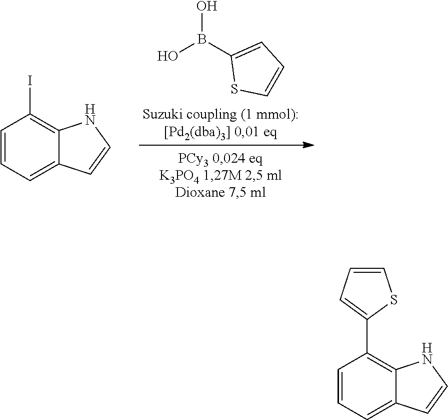 [SMILES: Ic1cccc2cc[nH]c12 ; OB(O)c1cccs1 ; c1csc(-c2cccc3cc[nH]c23)c1]

804 mg of 2-thienylboronic acid (5.71 mmol), 1.388 g of 7-iodoindole (6.28 mmol), 52 mg of [Pd₂(dba)₃] (0.057 mmol) and 39 mg of PCy₃ (0.14 mmol) are weighed out into a 70 ml autoclave, blanketed with an inert gas, 50 ml of dioxane and 8 ml of 1.27 M K₃PO₄ solution are added. The autoclave is sealed, and the contents are stirred at 100° C. for 24 h. The reaction mixture is taken up in 30 ml of dichloromethane and washed 3× with H₂O, the aqueous phase is then extracted 3× with 30 ml of dichloromethane each time, the organic phase is dried over MgSO₄, filtered off and concentrated in vacuo. The product is isolated with the aid of a silica-gel column (dichloromethane:hexane 2:8, R_{f}=0.17). Yield 82%.

¹H NMR (DCM-d₂, 400.13 MHz): δ 8.61-8.80 (m, 1H), 7.67-7.71 (m, 1H), 7.40-7.45 (m, 3H), 7.27-7.29 (m, 1H), 7.23-70.25 (m, 1H), 7.20-7.23 (m, 1H), 6.67-6.69 (m, 1H).

¹³C NMR (DCM-d₂, 100.13 MHz): δ 141.79, 133.65, 129.26, 128.56, 125.41, 125.34, 125.01, 122.19, 121.06, 120.69, 118.93, 103.65.

### Example 5

### Synthesis of the Ligand 8-PyQ (8-(1H-pyrrol-2-yl)quinoline)

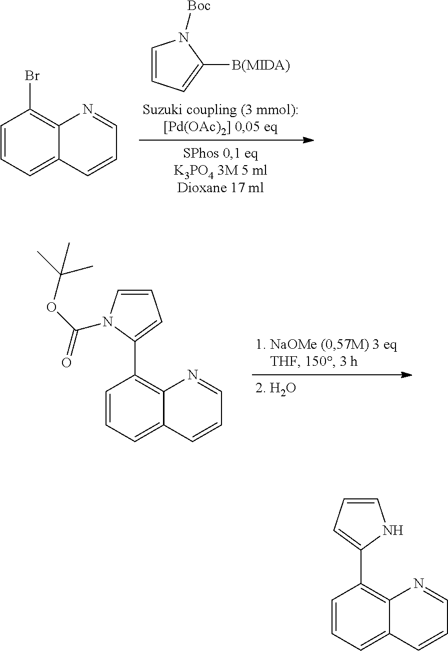

Step a)

1.06 g of N-Boc-6-methyl-2-(1H-pyrrol-2-yl)-1,3,6,2-dioxazaborocane-4,8-dione (3.28 mmol), 568 mg of 8-bromoquinoline (2.73 mmol), 31 mg of Pd(OAc)₂ (0.14 mmol) and 112 mg of SPhos (0.28 mmol) are weighed out into a 20 ml microwave glass vessel, blanketed with inert gas, 17 ml of dioxane are added, and 5 ml of 3 M K₃PO₄ solution are added dropwise. The vessel is sealed, and the contents are stirred in the microwave at 60° C. for 21 h. The reaction mixture is taken up in 30 ml of dichloromethane, washed 2× with H₂O, the aqueous phase is extracted 3× with 30 ml of dichloromethane each time, the organic phase is dried over MgSO₄, filtered off and concentrated in vacuo. The product (N-Boc-8-PyQ) is isolated with the aid of a silica-gel column (acetone:hexane 3:7, R_{f}=0.85).

Step b)

The N-Boc-8-PyQ obtained in step a) is dissolved in 8 ml of THF in a 30 ml pressure vessel under protective-gas atmosphere, and 12 ml of NaOMe soln. (0.57 M in methanol) are subsequently added. The vessel is sealed in a pressure-tight manner and stirred in a microwave at 150° C. for 3 h. During this time, the pressure continuously increases to 18 bar. The reaction mixture is then cooled to room temperature, added to 60 ml of H₂O, then extracted three times with 30 ml of diethyl ether each time, dried over MgSO₄ and concentrated in vacuo. The product is isolated with the aid of a silica-gel column (acetone:hexane 3:7, R_{f}=0.91). Yield 73%.

¹H NMR (DCM-d₂, 400.13 MHz): δ 12.41-12.83 (m, 1H), 8.91-8.95 (m, 1H), 8.20-8.23 (m, 1H), 8.11-8.15 (m, 1H), 7.62-7.65 (m, 1H), 7.53-7.57 (m, 1H), 7.43-7.47 (m, 1H), 6.99-7.02 (m, 1H), 6.87-6.91 (m, 1H), 6.29-6.33 (m, 1H).

¹³C NMR (DCM-d₂, 100.13 MHz): δ 149.32, 145.08, 137.68, 131.97, 129.80, 129.55, 127.36, 125.61, 125.44, 121.49, 119.53, 109.45, 107.57.

### Example 6

### Synthesis of the Ligand 7-BTpCa (1-(benzo[b]thiophen-2-yl)-9H-carbazole)

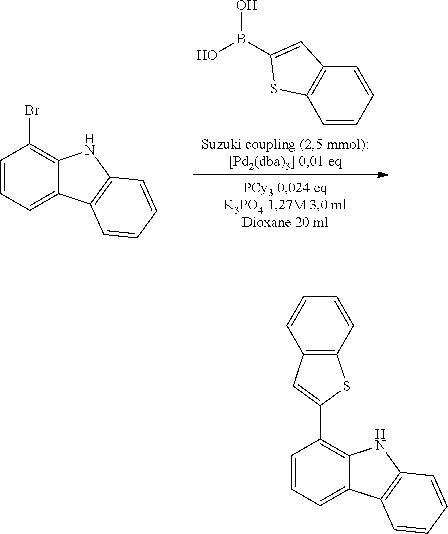 [SMILES: Brc1cccc2c1[nH]c1ccccc12 ; OB(O)c1cc2ccccc2s1 ; c1ccc2sc(-c3cccc4c3[nH]c3ccccc34)cc2c1]

1.59 g of 2-benzothienylboric acid (8.94 mmol), 2 g of 1-bromo-9H-carbazole (8.13 mmol), 74.0 mg of [Pd₂(dba)₃] (0.08 mmol) and 54.0 mg of PCy₃ (0.20 mmol) are weighed out into a 250 ml pressure vessel, blanketed with an inert gas, 75 ml of dioxane and 11 ml of 1.27 M K₃PO₄ soln. are added dropwise. The vessel is sealed, and the contents are stirred at 140° C. for 24 h. The reaction mixture is taken up with 30 ml of DCM and washed 3× with H₂O, the aqueous phase is then extracted 3× with 30 ml of DCM each time, the org. phase is dried over MgSO₄, filtered off and concentrated in vacuo. The product is isolated with the aid of a silica-gel column (dichloromethane:hexane 3:7, R_{f}=0.43). Yield 76%.

¹H NMR (DCM-d₂, 400.13 MHz): δ 8.79 (bs, 1H), 8.13 (m, 2H), 7.94 (m, 1H), 7.90 (m, 1H), 7.66-7.71 (m, 2H), 7.54 (m, 1H), 7.38-7.50 (m, 3H), 7.34 (m, 1H), 7.29 (m, 1H).

¹³C NMR (DCM-d₂, 100.13 MHz): δ 141.78, 141.11, 140.21, 140.01, 137.56, 126.86, 126.46, 125.36, 125.09, 124.72, 124.15, 123.85, 122.79, 121.93, 121.08, 120.97, 120.48, 120.41, 118.37, 111.56.

### Part 2: Complex Syntheses

### Example 7

### Synthesis of [Cu(7-Tpln)(Xantphos)]

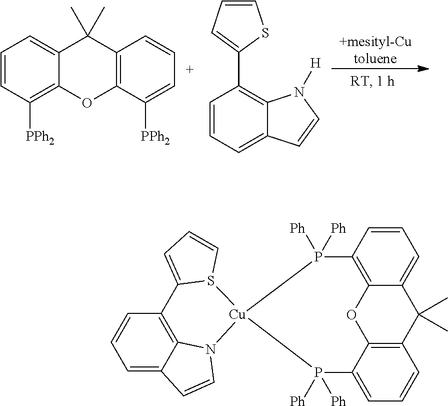

35.0 mg of mesityl-Cu and 3 ml of toluene are added to 38.2 mg (0.19 mmol) of 7-Tpln and 110.9 mg (0.19 mmol) of xantphos in a glove box. A yellow/orange solution and a yellow solid forms. The solid is filtered off, the solution is dried in vacuo, dissolved in dichloromethane and covered with a layer of hexane. Orange crystals form. Under UV (356 nm), these luminesce intensely white, the solution luminesces intensely blue. Yield: 92%.

¹H NMR (DCM-d₂, 400.13 MHz): δ 7.60-7.63 (m, 2H), 7.56-7.59 (m, 1H), 7.23-7.28 (m, 2H), 7.15-7.20 (m, 2H), 6.95-7.15 (m, 20H), 6.84-6.89 (m, 2H), 6.43-6.50 (m, 3H), 6.35-6.37 (m, 1H), 6.16-6.19 (m, 1H), 1.73 (s, 6H).

¹³C{¹H} NMR (DCM-d₂, 100.13 MHz): δ 155.46, 144.58, 143.53, 138.32, 134.48, 134.16, 133.64, 131.76, 130.18, 129.83, 128.82, 128.61, 126.99, 125.16, 123.33, 122.07, 121.60, 120.85, 120.24, 117.42, 116.01, 100.24, 36.48, 28.47, 28.39.

³¹P{¹H} NMR (DCM-d₂, 161.98 MHz): δ −15.19.

The solution luminescence spectrum of [Cu(7-Tpln)(xantphos)] has an emission maximum at 458 nm, the solid spectrum an emission maximum at 475 nm and the spectrum in polystyrene matrix has an emission maximum at 457 nm.

### Example 8

### Synthesis of [Cu(7-BTpln)(Dppb)]

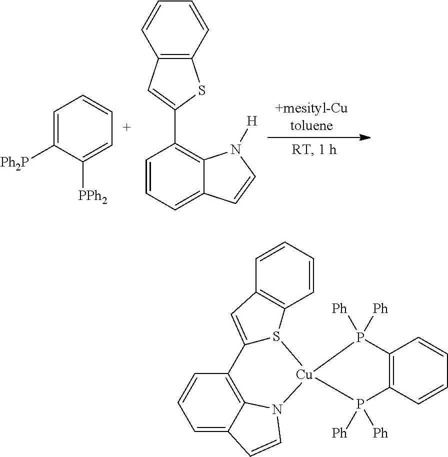

24.9 mg of mesityl-Cu and 3 ml of toluene are added to 34.0 mg (0.14 mmol) of 7-BTpln and 60.9 mg (0.14 mmol) of dppb in a glove box. A yellow solution forms. This is filtered off, dried in vacuo, dissolved in dichloromethane and covered with a layer of hexane. Yellow crystals form. Under UV (356 nm), these luminesce intensely yellow. Yield: 61%.

¹H NMR (DCM-d₂, 400.13 MHz): δ 7.61-7.66 (m, 2H), 7.48-7.51 (m, 4H), 7.46-7.47 (m, 1H), 7.45-7.46 (m, 1H), 7.38-7.39 (m, 1H), 7.21-7.23 (m, 1H), 7.08-7.20 (m, 20H), 6.86-6.90 (m, 1H), 6.80-6.84 (m, 1H), 6.56-6.57 (m, 1H), 6.23-6.26 (m, 1H).

¹³C{¹H} NMR (DCM-d₂, 100.13 MHz): δ 142.66, 142.34, 141.53, 139.68, 135.11, 134.65, 133.51, 132.09, 131.20, 130.14, 129.19, 125.69, 124.38, 124.08, 123.78, 122.42, 121.90, 121.17, 120.59, 120.23, 117.96, 116.16, 100.68.

³¹P{¹H} NMR (DCM-d₂, 161.98 MHz): δ −9.38.

The luminescence spectrum of the solid has an emission maximum at 501 nm and the spectrum in polystyrene matrix has an emission maximum at 526 nm.

### Example 9

### Synthesis of [Cu(7-BTpln)(PPh₃)₂]

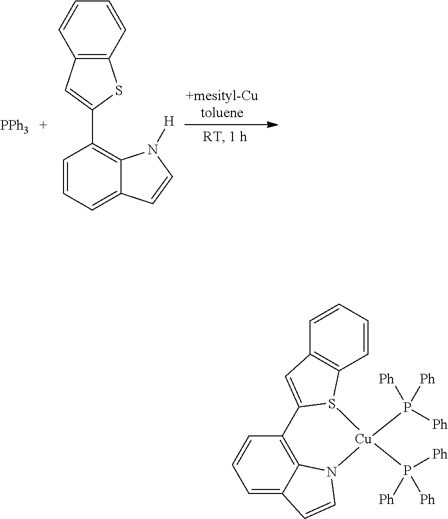

26.5 mg of mesityl-Cu and 3 ml of toluene are added to 36.2 mg (0.15 mmol) of 7-BTpln and 76.2 mg (0.29 mmol) of PPh₃ in a glove box. A yellow solution forms. This is covered with a layer of hexane. Yellow crystals form. Under UV (356 nm), these luminesce intensely blue, the solution likewise luminesces intensely blue. Yield: 81%.

¹H NMR (DCM-d₂, 400.13 MHz): δ 7.65-7.67 (m, 1H), 7.58-7.61 (m, 1H), 7.28-7.35 (m, 8H), 7.18 (m, 1H), 7.15-7.18 (m, 1H), 7.09-7.14 (m, 13H), 6.96-7.03 (m, 12H), 6.86-6.93 (m, 2H), 6.52-6.53 (m, 1H).

¹³C{¹H} NMR (DCM-d₂, 100.13 MHz): δ 144.02, 143.79, 141.52, 138.96, 138.40, 134.09, 133.67, 132.37, 130.18, 129.05, 125.51, 124.13, 123.79, 122.96, 121.06, 120.37, 120.18, 118.21, 116.39, 100.89.

³¹P{¹H} NMR (DCM-d₂, 161.98 MHz): δ −1.98.

The luminescence spectrum of the solid has an emission maximum at 483 nm, the spectrum in solution in dichloromethane has an emission maximum at 476 nm and the spectrum in polystyrene matrix has an emission maximum at 478 nm.

### Example 10

### Synthesis of [Cu(7-BTpln)(Xantphos)]

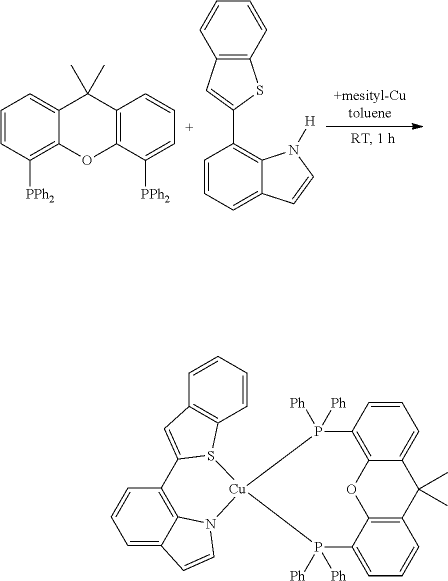

27.7 mg of mesityl-Cu and 3 ml of toluene are added to 37.8 mg (0.15 mmol) of 7-BTpln and 87.7 mg (0.15 mmol) of xantphos in a glove box. A yellow solution forms. This is filtered off and covered with a layer of hexane. Yellow crystals form. Under UV (356 nm), these luminesce intensely blue, the solution likewise luminesces intensely blue. Yield: 85%.

¹H NMR (DCM-d₂, 400.13 MHz): δ 7.60-7.63 (m, 1H), 7.54-7.57 (m, 2H), 7.40-7.44 (m, 1H), 7.17-7.26 (m, 5H), 7.10-7.12 (m, 1H), 6.98-7.09 (m, 12H), 6.87-6.96 (m, 10H), 6.77-6.80 (m, 1H), 6.42-6.47 (m, 2H), 6.32-6.33 (m, 1H), 1.78 (s, 3H), 1.59 (s, 3H).

¹³C{¹H} NMR (DCM-d₂, 100.13 MHz): δ 155.27, 144.24, 143.63, 141.35, 138.65, 133.90, 132.91, 132.39, 132.03, 131.51, 129.90, 129.53, 128.79, 128.75, 127.09, 125.19, 125.13, 123.98, 123.73, 122.54, 121.65, 120.98, 120.41, 117.97, 116.05, 100.24, 36.42, 29.95, 26.86.

³¹P{¹H} NMR (DCM-d₂, 161.98 MHz): δ −15.67.

The luminescence spectrum of the solid has an emission maximum at 487 nm, the spectrum in solution in dichloromethane has an emission maximum at 480 nm and the spectrum in polystyrene matrix has an emission maximum at 464 nm.

### Example 11

### Synthesis of [Cu(7-Pyln)(Dppb)]

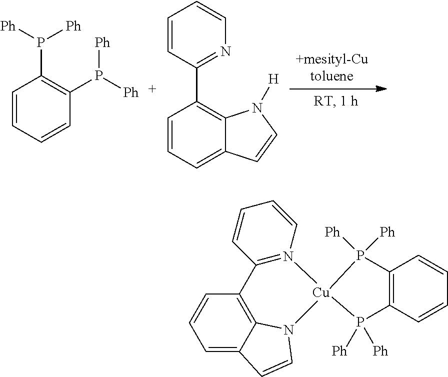

45.6 mg of mesityl-Cu and 3 ml of toluene are added to 48.5 mg (0.25 mmol) of 7-Pyln and 111.5 mg (0.25 mmol) of dppb in a glove box. A yellow solution forms. This is filtered and covered with a layer of hexane. Orange-red crystals form. Under UV (356 nm), these luminesce intensely orange. Yield: 71%.

¹H NMR (DCM-d₂, 400.13 MHz): δ 8.09-8.12 (m, 1H), 7.71-7.73 (m, 1H), 7.51-7.59 (m, 7H), 7.38-7.40 (m, 1H), 7.17-7.35 (m, 20H), 6.90-6.94 (m, 1H), 6.59-6.61 (m, 1H), 6.38-6.43 (m, 1H).

¹³C{¹H} NMR (DCM-d₂, 100.13 MHz): δ 159.88, 152.01, 143.64, 143.32, 143.11, 143.00, 140.47, 138.54, 136.98, 135.23, 133.61, 130.92, 129.06, 122.84, 122.62, 122.04, 119.78, 119.07, 115.86, 99.81.

³¹P{¹H} NMR (DCM-d₂, 161.98 MHz): δ −11.81.

The luminescence spectrum of the solid has an emission maximum at 532 nm and the spectrum in polystyrene matrix has an emission maximum at 524 nm.

### Example 12

### Synthesis of [Cu(7-Pyln)(PPh₃)₂]

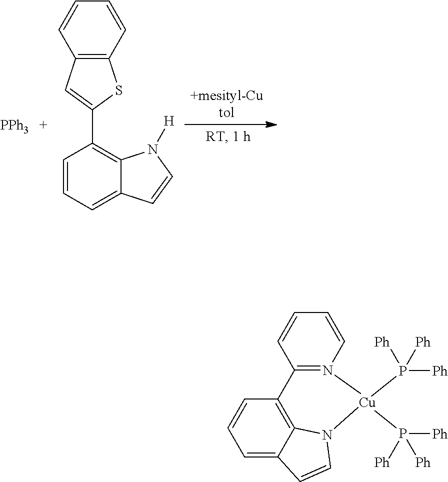

37.9 mg of mesityl-Cu and 3 ml of toluene are added to 40.3 mg (0.21 mmol) of 7-Pyln and 108.8 mg (0.42 mmol) of PPh₃ in a glove box. A yellow solution forms. This is filtered, dried in vacuo, dissolved in dichloromethane and covered with a layer of hexane. Orange crystals form. Under UV (356 nm), these luminesce intensely orange. Yield: 77%.

¹H NMR (DCM-d₂, 400.13 MHz): δ 8.20-8.23 (m, 1H), 8.13-8.16 (m, 1H), 7.76-7.79 (m, 1H), 7.65-7.71 (m, 1H), 7.56-7.59 (m, 1H), 7.23-7.38 (m, 31H), 6.99. 7.03 (m, 1H), 6.74-6.79 (m, 1H), 6.53-6.54 (m, 1H).

¹³C{¹H} NMR (DCM-d₂, 100.13 MHz): δ 159.85, 151.81, 142.90, 140.28, 137.54, 135.33, 134.19, 133.39, 129.92, 129.06, 123.81, 122.63, 121.90, 120.41, 119.60, 116.25, 100.30.

³¹P{¹H} NMR (DCM-d₂, 161.98 MHz): δ −1.67.

The luminescence spectrum of the solid has an emission maximum at 565 nm.

### Example 13

### Synthesis of [Cu(7-Pyln)(Xantphos)]

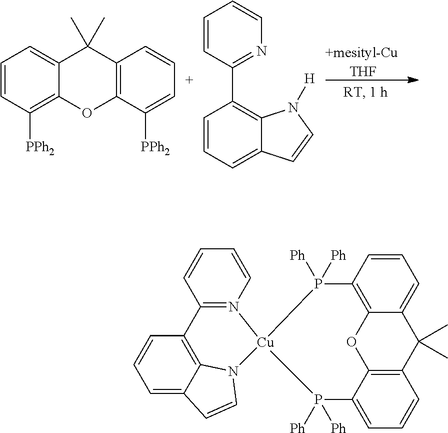

16.7 mg of mesityl-Cu and 3 ml of THF are added to 17.8 mg (0.09 mmol) of 7-Pyln and 53.0 mg (0.09 mmol) of xantphos in a glove box. A yellow solution forms. This is filtered off, concentrated in vacuo, dissolved in dichloromethane and covered with a layer of hexane. Orange crystals form. Under UV (356 nm) these luminesce intensely orange, the solution likewise luminesces intensely orange. Yield: 79%.

¹H NMR (DCM-d₂, 400.13 MHz): δ 8.06-8.10 (m, 1H), 8.02-8.06 (m, 1H), 7.65-7.68 (m, 1H), 7.60-7.63 (m, 2H), 7.55-7.59 (m, 1H), 7.43-7.46 (m, 1H), 7.18-7.23 (m, 2H), 6.96-7.17 (m, 20H), 6.92-6.96 (m, 1H), 6.69-6.71 (m, 1H), 6.56-6.59 (m, 1H), 6.43-6.47 (m, 2H), 6.21-6.23 (m, 1H), 1.77 (s, 6H).

¹³C{¹H} NMR (DCM-d₂, 100.13 MHz): δ 160.62, 155.87, 150.70, 139.46, 137.15, 134.43, 134.15, 133.81, 131.41, 129.69, 129.45, 128.70, 126.43, 124.98, 123.96, 123.00, 122.90, 122.82, 122.24, 120.10, 119.09, 115.64, 99.12, 36.70, 28.33, 28.05.

³¹P{¹H} NMR (DCM-d₂, 161.98 MHz): δ −16.04.

The luminescence spectrum of the solid has an emission maximum at 582 nm.

### Example 14

### Synthesis of [Cu(7-Tpln)(Dppb)]

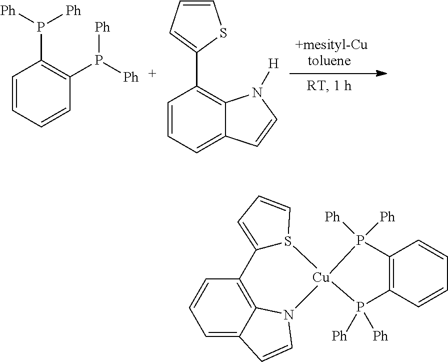

42.5 mg of mesityl-Cu and 3 ml of toluene are added to 46.3 mg (0.23 mmol) of 7-Tpln and 103.7 mg (0.23 mmol) of dppb in a glove box. A yellow solution forms. This is dried in vacuo, dissolved in dichloromethane and covered with a layer of hexane. Yellow crystals form. Under UV (356 nm), these luminesce yellow. Yield: 68%.

¹H NMR (DCM-d₂, 400.13 MHz): δ 7.53-7.56 (m, 1H), 7.51-7.53 (m, 1H), 7.45-7.46 (m, 1H), 7.25-7.29 (m, 10H), 7.15-7.22 (m, 9H), 7.04-7.10 (m, 5H), 6.75-6.84 (m, 3H), 6.53-6.54 (m, 1H), 6.16-618 (m, 1H).

¹³C{¹H} NMR (DCM-d₂, 100.13 MHz): δ 142.27, 139.14, 135.06, 133.72, 132.09, 131.31, 130.69, 130.27, 129.48, 129.19, 127.77, 125.66, 123.89, 123.20, 122.28, 120.36, 117.35, 116.10, 100.62.

³¹P{¹H} NMR (DCM-d₂, 161.98 MHz): δ −9.12.

The fluorescence spectrum of the solid has an emission maximum at 504 nm and the spectrum in polystyrene matrix has an emission maximum at 528 nm.

### Example 15

### Syntheses of [Cu(7-Tpln)(PPh₃)₂]

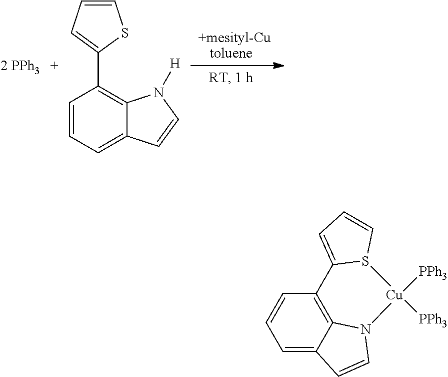

42.5 mg of mesityl-Cu and 3 ml of toluene are added to 46.3 mg (0.23 mmol) of 7-Tpln and 121.9 mg (0.46 mmol) of PPh₃ in a glove box. A yellow solution forms. This is filtered, dried in vacuo, dissolved in dichloromethane and covered with a layer of hexane. Yellow crystals form. Under UV (356 nm), these luminesce intensely blue, the solution likewise luminesces intensely blue. Yield: 88%.

¹H NMR (DCM-d₂, 400.13 MHz): δ 7.59-7.62 (m, 1H), 7.31-7.38 (m, 7H), 7.17-7.22 (m, 12H), 7.08-7.14 (m, 14H), 6.84-6.90 (m, 2H), 6.59-6.61 (m, 1H), 6.51-6.52 (m, 1H).

¹³C{¹H} NMR (DCM-d₂, 100.13 MHz): δ 144.40, 143.42, 138.70, 134.17, 133.97, 132.24, 130.19, 129.18, 129.07, 123.71, 122.70, 120.50, 120.36, 117.65, 1160.33, 100.88.

³¹P{¹H} NMR (DCM-d₂, 161.98 MHz): δ −1.92.

The luminescence spectrum of the solid has an emission maximum at 469 nm, the spectrum in solution in dichloromethane has an emission maximum at 468 nm and the spectrum in polystyrene matrix has an emission maximum at 457 nm.

### Example 16

### Synthesis of [Cu(8-PyQ)(PPh₃)₂]

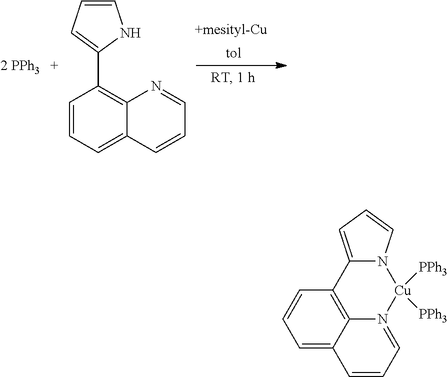

38.4 mg of mesityl-Cu and 3 ml of toluene are added to 40.8 mg (0.21 mmol) of 8-PyQ and 110.2 mg (0.42 mmol) of PPh₃ in a glove box. A red solution forms. This is filtered off, and the solvent is allowed to evaporate off slowly. Red crystals form. Under UV (356 nm), these luminesce intensely red, the solution likewise luminesces intensely red. Yield: 78%.

¹H NMR (DCM-d₂, 400.13 MHz): δ 8.37-8.39 (m, 1H), 8.26-8.29 (m, 1H), 8.14-8.17 (m, 1H), 7.50-7.55 (m, 1H), 7.45-7.48 (m, 1H), 7.30-7.39 (m, 30H), 7.03-7.07 (m, 1H), 6.96-6.97 (m, 1H), 6.91-6.93 (m, 1H), 6.23-6.25 (m, 1H).

¹³C{¹H} NMR (DCM-d₂, 100.13 MHz): δ 152.64, 143.06, 139.65, 137.13, 135.59, 135.30, 134.26, 133.67, 131.17, 129.98, 129.16, 128.07, 127.90, 123.30, 120.27, 109.55, 109.45.

³¹P{¹H} NMR (DCM-d₂, 161.98 MHz): δ −0.79.

The luminescence spectrum of the solid has an emission maximum at 645 nm, the spectrum in solution in dichloromethane has an emission maximum at 617 nm and the spectrum in polystyrene matrix has an emission maximum at 582 nm.

### Example 17

### Synthesis of [Cu(8-PvQ)(Xantphos)]

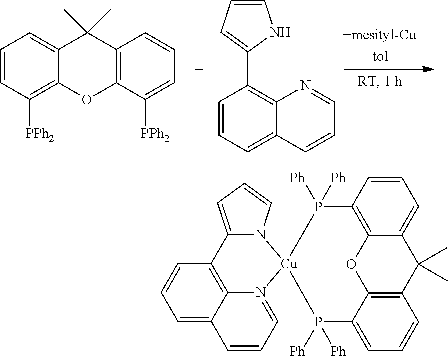

35.6 mg of mesityl-Cu and 3 ml of toluene are added to 37.8 mg (0.20 mmol) of 8-PyQ and 112.6 mg (0.20 mmol) of xantphos in a glove box. A red solution forms. This is filtered off, and the solvent is allowed to evaporate off slowly. Red crystals form. Under UV (356 nm), these luminesce intensely red, the solution likewise luminesces intensely red. Yield: 74%.

¹H NMR (DCM-d₂, 400.13 MHz): δ 8.16-8.20 (m, 2H), 7.91-7.94 (m, 1H), 7.58-7.61 (m, 2H), 7.48-7.52 (m, 1H), 7.34-7.37 (m, 1H), 7.10-7.22 (m, 8H), 7.06-7.08 (m, 2H), 6.96-7.05 (m, 12H), 6.81-6.82 (m, 1H), 6.67-6.71 (m, 1H), 6.40-6.45 (m, 2H), 6.32-6.33 (m, 1H), 5.99-6.01 (m, 1H) 1.79 (s, 3H), 1.73 (s, 3H).

¹³C{¹H} NMR (DCM-d₂, 100.13 MHz): δ 155.82, 150.34, 138.20, 134.20, 133.84, 133.03, 132.76, 132.66, 131.70, 131.42, 129.68, 129.48, 128.69, 128.54, 128.41, 127.97, 127.64, 126.47, 125.02, 122.61, 119.70, 109.37, 108.89, 36.69, 30.27, 27.82.

The luminescence spectrum of the solid has an emission maximum at 557 and 606 nm, the spectrum in solution in toluene has an emission maximum at 603 nm and the spectrum in polystyrene matrix has an emission maximum at 568 and 618 nm.

### Example 18

### Synthesis of [Cu(8-PyQ)(dppb)]

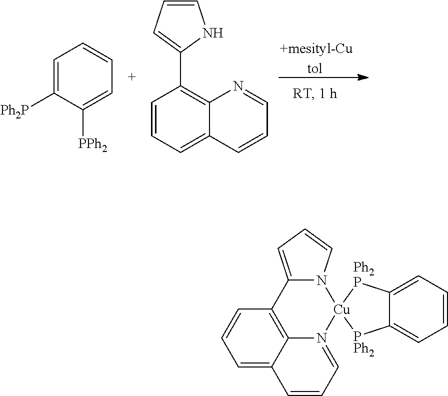

32.6 mg of mesityl-Cu and 3 ml of toluene are added to 34.6 mg (0.18 mmol) of 8-PyQ and 79.5 mg (0.18 mmol) of dppb in a glove box. A dark-red solution forms. This is filtered and covered with a layer of n-hexane. Red crystals form. Under UV (356 nm), these luminesce intensely red, the solution likewise luminesces intensely red. Yield: 70%.

¹H NMR (DCM-d₂, 400.13 MHz): δ 8.24 (m, 1H), 7.92 (m, 1H), 7.51-7.55 (m, 4H), 7.44 (m, 1H), 7.38 (m, 1H), 7.36 (m, 1H), 7.28-7.31 (m, 4H), 7.21-7.26 (m, 14H), 7.12 (m, 1H), 7.07 (m, 1H), 6.94-6.98 (m, 2H), 6.47 (m, 1H), 6.31 (m, 1H).

¹³C{¹H} NMR (DCM-d₂, 100.13 MHz): δ 152.15, 143.42, 143.37, 138.24, 137.48, 135.30, 134.90, 133.55, 133.07, 131.01, 130.70, 129.80, 129.54, 129.10, 127.65, 127.05, 122.85, 119.60, 109.31, 109.19.

³¹P{¹H} NMR (DCM-d₂, 161.98 MHz): δ −9.43 (s).

The luminescence spectrum of the toluene solution has an emission maximum at 618 nm and the spectrum in polystyrene matrix has an emission maximum at 580.

### Example 19

### Synthesis of [Cu(7-BTpCa)(PPh₃)₂]

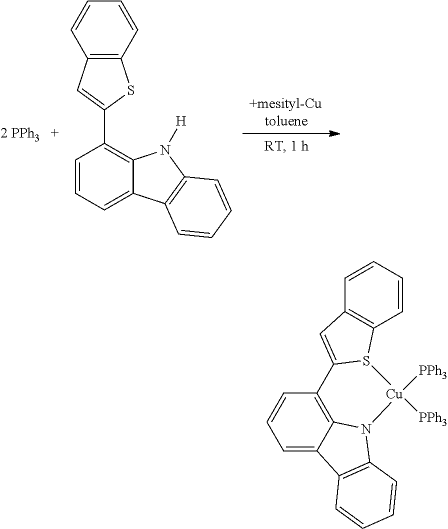

61.0 mg of mesityl-Cu and 3 ml of toluene are added to 100.0 mg (0.33 mmol) of 7-BTpCa and 175.2 mg (0.67 mmol) of PPh₃ in a glove box. A yellow solution forms. This is filtered off and covered with a layer hexane. Yellow crystals form. Under UV (356 nm), these luminesce intensely green, the solution likewise luminesces intensely green. Yield: 85%.

¹H NMR (DCM-d₂, 400.13 MHz): δ 8.16 (m, 1H), 8.08-8.11 (m, 1H), 7.64 (m, 1H), 7.50 (m, 1H), 7.29-7.34 (m, 7H), 7.21-7.24 (m, 2H), 7.11 (m, 12H), 7.00-7.06 (m, 14H), 6.94 (m, 2H), 6.76 (m, 1H).

¹³C{¹H} NMR (DCM-d₂, 100.13 MHz): δ 148.52, 143.72, 141.55, 138.46, 134.18, 133.72, 130.22, 129.08, 125.58, 125.47, 124.18, 124.15, 123.90, 123.86, 123.80, 123.27, 120.97, 120.85, 120.73, 119.89, 116.61, 115.79, 115.66, 115.27.

³¹P{¹H} NMR (DCM-d₂, 161.98 MHz): δ −1.81 (s).

The luminescence spectrum of the solid has an emission maximum at 506 nm, the spectrum in solution in dichloromethane has an emission maximum at 499 nm and the spectrum in polystyrene matrix has an emission maximum at 504 nm.

### Example 20

### Synthesis of [Cu(7-BTpCa)(Xantphos)]

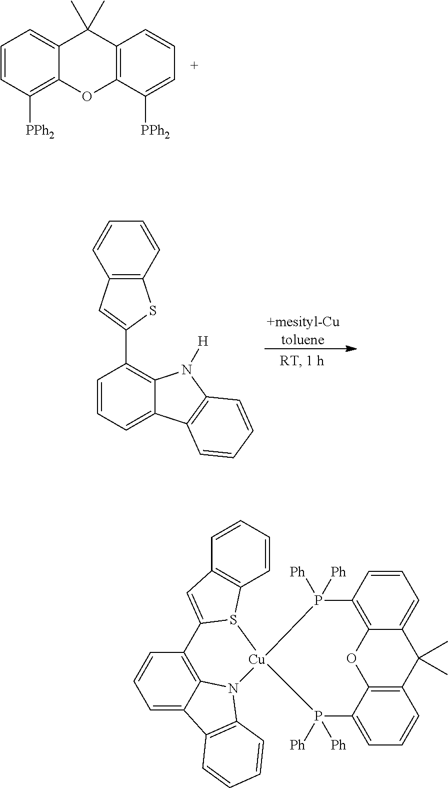

61.0 mg of mesityl-Cu and 3 ml of toluene are added to 100.0 mg (0.33 mmol) of 7-BTpCa and 193.0 mg (0.33 mmol) of xantphos in a glove box. A yellow suspension forms. This is filtered off, concentrated in vacuo, dissolved in DCM and covered with a layer of hexane. Yellow crystals form. Under UV (356 nm) these luminesce intensely green, the solution likewise luminesces intensely green. Yield: 86%.

¹H NMR (DCM-d₂, 400.13 MHz): δ 8.13 (m, 1H), 7.99 (m, 1H), 7.57 (m, 2H), 7.47 (m, 1H), 7.14-7.35 (m, 8H), 6.81-7.08 (m, 21H), 6.69-6.75 (m, 2H), 6.50 (m, 2H), 1.87 (s, 3H), 1.51 (s, 3H).

¹³C{¹H} NMR (DCM-d₂, 100.13 MHz): δ 155.12, 148.80, 134.48, 134.27, 133.83, 133.56, 132.38, 132.20, 131.69, 131.65, 130.12, 129.70, 128.84, 128.73, 127.36, 126.70, 125.42, 125.31, 125.25, 124.26, 123.96, 123.46, 123.36, 121.99, 120.88, 119.79, 119.68, 115.64, 115.00, 114.78, 35.96, 32.17, 26.16.

³¹P{¹H} NMR (DCM-d₂, 161.98 MHz): δ −15.86 (s).

The luminescence spectrum of the solid has an emission maximum at 508 nm, the spectrum in solution in dichloromethane has an emission maximum at 501 nm and the spectrum in polystyrene matrix has an emission maximum at 495 nm.

### Example 21

### Synthesis of [Cu(7-BTpCa)(dppb)]

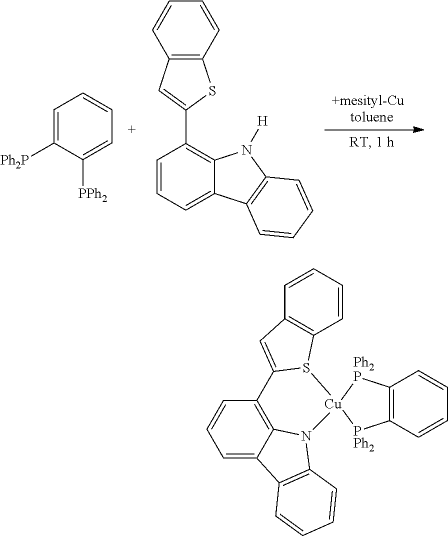

61.0 mg of mesityl-Cu and 3 ml of toluene are added to 100.0 mg (0.33 mmol) of 7-BTpCa and 149.3 mg (0.33 mmol) of dppb in a glove box. A yellow solution forms. This is filtered off and covered with a layer of hexane. Yellow crystals form. Under UV (356 nm), these luminesce intensely green, the solution likewise luminesces intensely green. Yield: 83%.

¹H NMR (DCM-d₂, 400.13 MHz): δ 8.17 (m, 1H), 8.14 (m, 1H), 7.70 (m, 1H), 7.61 (m, 1H), 7.54-7.57 (m, 2H), 7.44 (s, 1H), 7.24-7.28 (m, 5H), 7.15 (m, 1H), 7.04-7.11 (m, 18H), 6.99 (m, 1H), 6.94-6.97 (m, 2H), 6.80 (m, 1H), 6.02 (m, 1H).

¹³C{¹H} NMR (DCM-d₂, 100.13 MHz): δ 148.34, 143.09, 141.87, 141.47, 138.19, 133.86, 133.05, 131.39, 130.68, 130.15, 129.47, 129.11, 127.00, 125.73, 125.37, 124.42, 123.95, 123.85, 123.77, 122.83, 121.09, 120.73, 119.93, 118.70, 117.04, 115.67, 114.91.

³¹P{¹H} NMR (DCM-d₂, 161.98 MHz): δ −10.01 (s).

The luminescence spectrum of the solid has an emission maximum at 514 nm auf and the spectrum in polystyrene matrix has an emission maximum at 518 nm.

### Production of the OLEDs

### 1) Vacuum-Processed Devices:

OLEDs according to the invention and OLEDs in accordance with the prior art are produced by a general process in accordance with WO 2004/058911, which is adapted to the circumstances described here (layer-thickness variation, materials used).

The results for various OLEDs are presented in the following examples. Glass plates with structured ITO (indium tin oxide) form the substrates to which the OLEDs are applied. The OLEDs have in principle the following layer structure: substrate/hole-transport layer 1 (HTL1) consisting of HTM doped with 3% of NDP-9 (commercially available from Novaled), 20 nm/hole-transport layer 2 (HTL2)/electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm

Firstly, vacuum-processed OLEDs are described. For this purpose, all materials are applied by thermal vapour deposition in a vacuum chamber. The emission layer here always consists of at least one matrix material (host material) and an emitting dopant (emitter), which is admixed with the matrix material or matrix materials in a certain proportion by volume by coevaporation. An expression such as M3:M2:Ex. (55%:35%:10%) here means that material M3 is present in the layer in a proportion by volume of 55%, M2 is present in the layer in a proportion of 35% and the Cu emitter according to Ex. is present in the layer in a proportion of 10%. Analogously, the electron-transport layer may also consist of a mixture of two materials. The precise structure of the OLEDs is shown in Table 1. The materials used for the production of the OLEDs are shown in Table 4.

The OLEDs are characterised by standard methods. For this purpose, the electroluminescence spectra, the external quantum efficiency (in %) and the voltage (measured at 300 cd/m² in V) are determined from current/voltage/luminance characteristic lines (IUL characteristic lines).

### Use of Compounds According to the Invention as Emitter Materials

The compounds according to the invention can be employed, inter alia, as emitter materials in the emission layer in OLEDs.

TABLE 1
Structure of the OLED

| | HTL2 | EBL | EML | HBL | ETL |
|---|---|---|---|---|---|
| Ex. | Thickness | Thickness | Thickness | Thickness | Thickness |
| D-Ex. 1 | HTM | EBM | M1:M4:Ex. 7 | HBM | ETM1:ETM2 |
| | 180 nm | 20 nm | (65%:30%:5%) | 10 nm | (50%:50%) |
| | | | 25 nm | | 25 nm |
| D-Ex. 2 | HTM | EBM | M1:M4:Ex. 8 | HBM | ETM1:ETM2 |
| | 180 nm | 20 nm | (65%:30%:5%) | 10 nm | (50%:50%) |
| | | | 25 nm | | 25 nm |
| D-Ex. 3 | HTM | EBM | M2:M4:Ex. 10 | HBM | ETM1:ETM2 |
| | 180 nm | 20 nm | (65%:30%:5%) | 10 nm | (50%:50%) |
| | | | 25 nm | | 25 nm |
| D-Ex. 4 | HTM | — | M1:M6:Ex. 11 | HBM | ETM1:ETM2 |
| | 180 nm | | (35%:40%:5%) | 10 nm | (50%:50%) |
| | | | 25 nm | | 25 nm |
| D-Ex. 5 | HTM | EBM | M1:M4:Ex. 13 | HBM | ETM1:ETM2 |
| | 180 nm | 20 nm | (65%:30%:5%) | 10 nm | (50%:50%) |
| | | | 25 nm | | 25 nm |
| D-Ex. 6 | HTM | EBM | M1:M3:Ex. 14 | HBM | ETM1:ETM2 |
| | 180 nm | 20 nm | (60%:35%:5%) | 10 nm | (50%:50%) |
| | | | 25 nm | | 25 nm |
| D-Ex. 7 | HTM | EBM | M1:M3:Ex. 17 | HBM | ETM1:ETM2 |
| | 180 nm | 20 nm | (60%:35%:5%) | 10 nm | (50%:50%) |
| | | | 25 nm | | 25 nm |
| D-Ex. 11 | HTM | EBM | M1:M3:Ex. 18 | HBM | ETM1:ETM2 |
| | 180 nm | 20 nm | (60%: 30%: 10%) | 10 nm | (50%:50%) |
| | | | 25 nm | | 25 nm |
| D-Ex. 12 | HTM | EBM | M1:M3:Ex. 20 | HBM | ETM1:ETM2 |
| | 180 nm | 20 nm | (60%:35%:5%) | 10 nm | (50%:50%) |
| | | | 25 nm | | 25 nm |
| D-Ex. 13 | HTM | EBM | M1:M3:Ex. 21 | HBM | ETM1:ETM2 |
| | 180 nm | 20 nm | (55%:35%:10%) | 10 nm | (50%:50%) |
| | | | 25 nm | | 25 nm |

TABLE 2
Results of the vacuum-processed OLEDs

| | EQE (%) | Voltage (V) | CIE x/y |
|---|---|---|---|
| Ex. | 300 cd/m² | 300 cd/m² | 300 cd/m² |
| D-Ex. 1 | 6.4 | 4.6 | 0.16/0.27 |
| D-Ex. 2 | 11.2 | 4.5 | 0.33/0.58 |
| D-Ex. 3 | 9.0 | 4.5 | 0.17/0.28 |
| D-Ex. 4 | 10.9 | 4.1 | 0.58/0.33 |
| D-Ex. 5 | 13.3 | 4.3 | 0.41/0.46 |
| D-Ex. 6 | 9.8 | 4.0 | 0.36/0.56 |
| D-Ex. 7 | 8.7 | 4.2 | 0.60/0.31 |
| D-Ex. 11 | 9.7 | 3.8 | 0.64/0.29 |
| D-Ex. 12 | 15.4 | 4.3 | 0.24/0.55 |
| D-Ex. 13 | 13.8 | 4.2 | 0.29/0.57 |

### 2) Solution-Processed Devices:

### A: From Soluble Functional Materials

The iridium complexes according to the invention can also be processed from solution, where they result in OLEDs which are significantly simpler as far as the process is concerned, compared with the vacuum-processed OLEDs, with nevertheless good properties. The production of components of this type is based on the production of polymeric light-emitting diodes (PLEDs), which has already been described many times in the literature (for example in WO 2004/037887). The structure is composed of substrate/ITO/PEDOT (80 nm)/interlayer (80 nm)/emission layer (80 nm)/cathode. To this end, use is made of substrates from Technoprint (soda-lime glass), to which the ITO structure (indium tin oxide, a transparent, conductive anode) is applied. The substrates are cleaned with DI water and a detergent (Deconex 15 PF) in a clean room and then activated by a UV/ozone plasma treatment. An 80 nm layer of PEDOT (PEDOT is a polythiophene derivative (Baytron P VAI 4083sp.) from H. C. Starck, Goslar, which is supplied as an aqueous dispersion) is then applied as buffer layer by spin coating, likewise in the clean room. The spin rate required depends on the degree of dilution and the specific spin coater geometry (typically for 80 nm: 4500 rpm). In order to remove residual water from the layer, the substrates are dried by heating on a hotplate at 180° C. for 10 minutes. The interlayer used serves for hole injection, in this case HIL-012 from Merck is used. The interlayer may alternatively also be replaced by one or more layers, which merely have to satisfy the condition of not being detached again by the subsequent processing step of EML deposition from solution. In order to produce the emission layer, the emitters according to the invention are dissolved in toluene together with the matrix materials. The typical solids content of such solutions is between 16 and 25 g/I if, as here, the typical layer thickness of 80 nm for a device is to be achieved by means of spin coating. The solution-processed devices comprise an emission layer comprising (polystyrene):M5:M6:Ex. (25%:25%:40%:10%). The emission layer is applied by spin coating in an inert-gas atmosphere, in the present case argon, and dried by heating at 130° C. for 30 min. Finally, a cathode is applied by vapour deposition from barium (5 nm) and then aluminium (100 nm) (high-purity metals from Aldrich, particularly barium 99.99% (Order No. 474711); vapour-deposition equipment from Lesker, inter alia, typical vapour-deposition pressure 5×10⁻⁶ mbar). Optionally, firstly a hole-blocking layer and then an electron-transport layer and only then the cathode (for example Al or LiF/AI) can be applied by vacuum vapour deposition. In order to protect the device against air and atmospheric moisture, the device is finally encapsulated and then characterised. The OLED examples given have not yet been optimised, Table 3 summarises the data obtained.

TABLE 3
Results with materials processed from solution

| | Emitter | EQE (%) | Voltage (V) | CIE x/y |
|---|---|---|---|---|
| Ex. | Ex. | 300 cd/m² | 300 cd/m² | 300 cd/m² |
| D-Ex. 8 | Ex. 9 | 6.4 | 5.0 | 0.17/0.34 |
| D-Ex. 9 | Ex. 12 | 7.6 | 4.9 | 0.59/0.35 |
| D-Ex. 10 | Ex. 15 | 4.9 | 5.4 | 0.17/0.29 |
| D-Ex. 10 | Ex. 16 | 5.5 | 5.1 | 0.66/0.33 |
| D-Ex. 14 | Ex. 19 | 9.5 | 4.8 | 0.26/0.59 |

TABLE 4
Structural formulae of the materials used

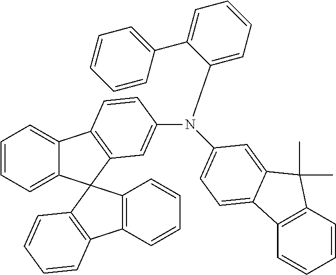 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM

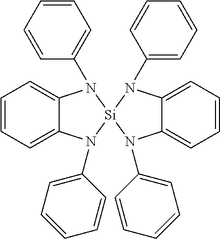 [SMILES: c1ccc(N2c3ccccc3N(c3ccccc3)[Si]23N(c2ccccc2)c2ccccc2N3c2ccccc2)cc1]

EBM

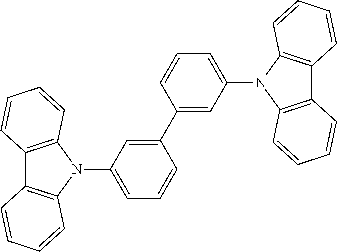 [SMILES: c1cc(-c2cccc(-n3c4ccccc4c4ccccc43)c2)cc(-n2c3ccccc3c3ccccc32)c1]

M1

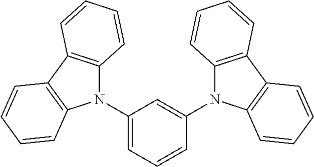 [SMILES: c1cc(-n2c3ccccc3c3ccccc32)cc(-n2c3ccccc3c3ccccc32)c1]

M2

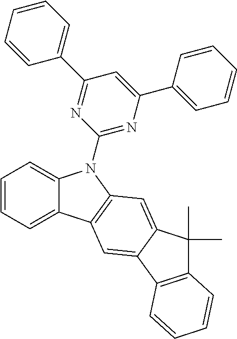 [SMILES: CC1(C)c2ccccc2-c2cc3c4ccccc4n(-c4nc(-c5ccccc5)cc(-c5ccccc5)n4)c3cc21]

M3

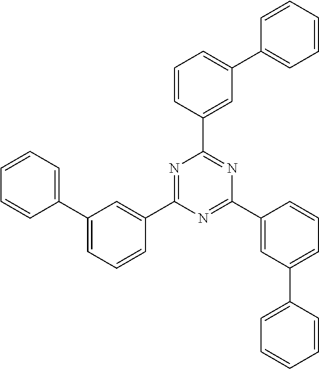 [SMILES: c1ccc(-c2cccc(-c3nc(-c4cccc(-c5ccccc5)c4)nc(-c4cccc(-c5ccccc5)c4)n3)c2)cc1]

M4 = HBM

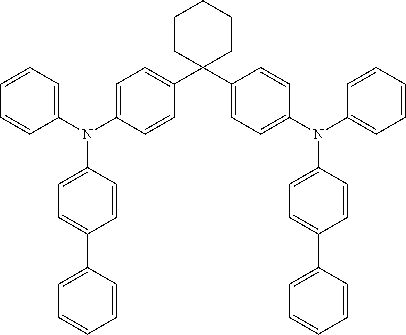 [SMILES: c1ccc(-c2ccc(N(c3ccccc3)c3ccc(C4(c5ccc(N(c6ccccc6)c6ccc(-c7ccccc7)cc6)cc5)CCCCC4)cc3)cc2)cc1]

M5

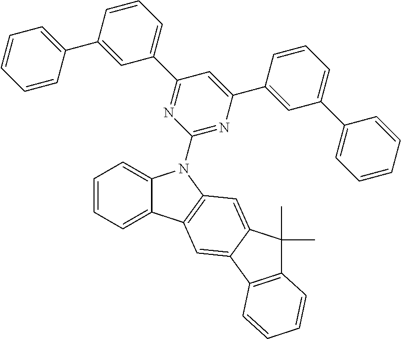 [SMILES: CC1(C)c2ccccc2-c2cc3c4ccccc4n(-c4nc(-c5cccc(-c6ccccc6)c5)cc(-c5cccc(-c6ccccc6)c5)n4)c3cc21]

M6

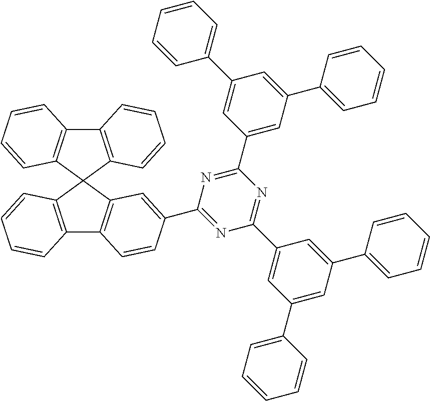 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM1

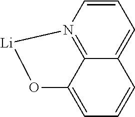

ETM2

### DESCRIPTION OF THE FIGURES

FIG. 1: Crystal structure of [Cu(7-Tpln)(xantphos)].

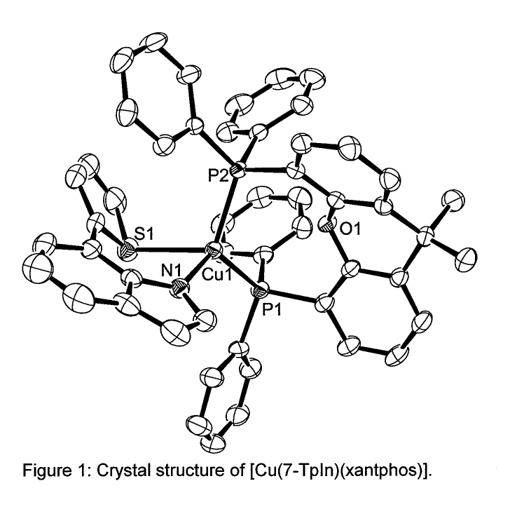

FIG. 2: Absorption and luminescence spectrum of [Cu(7-Tpln)(L′)]. L′: X=xantphos, P=(PPh₃)₂, D=dppb. (a: spectrum of solution in dichloromethane, b: spectrum of solid, c: spectrum in polystyrene matrix).

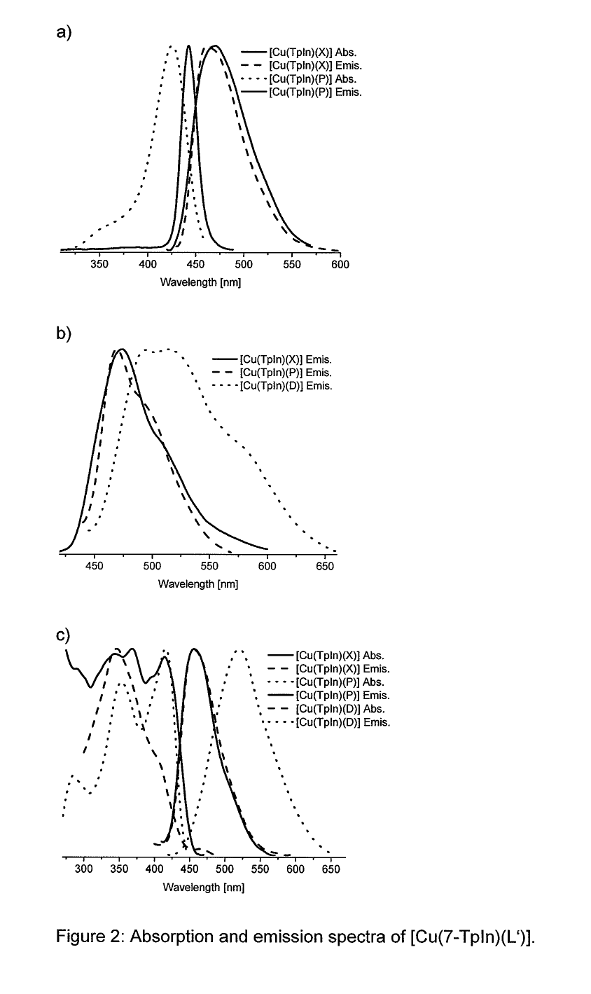

FIG. 3: Crystal structure of [Cu(7-BTpln)(dppb)].

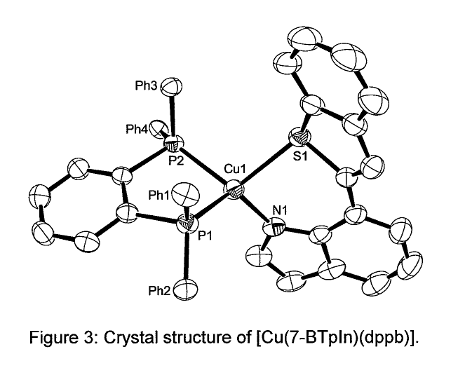

FIG. 4: Absorption and luminescence spectrum of [Cu(7-BTpln)(L′)]. L′: X=xantphos, P=(PPh₃)₂, D=dppb. (a: spectrum of solution in dichloromethane, b: spectrum of solid, c: spectrum in polystyrene matrix).

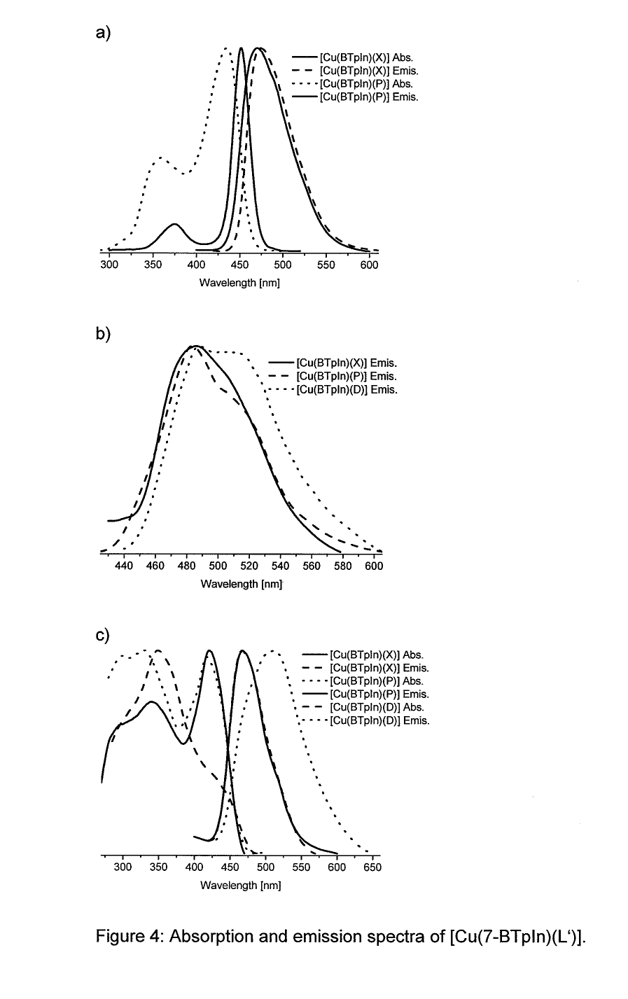

FIG. 5: Crystal structure of [Cu(7-BTpCa)(PPh₃)₂].

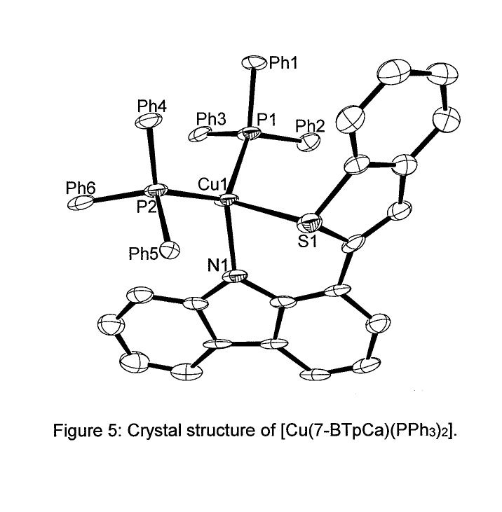

FIG. 6: Absorption and luminescence spectrum of [Cu(7-BTpCa)(L′)]. L′: X=xantphos, P=(PPh₃)₂, D=dppb. (a: spectrum of solution in dichloromethane, b: spectrum of solid, c: spectrum in polystyrene matrix).

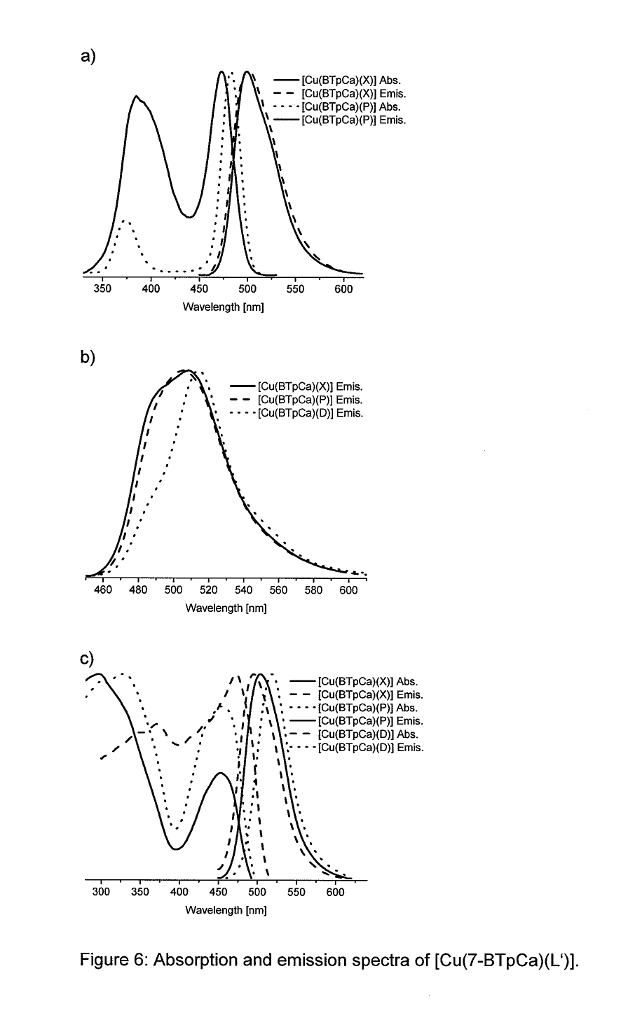

FIG. 7: Crystal structure of [Cu(7-Pyln)(xantphos)].

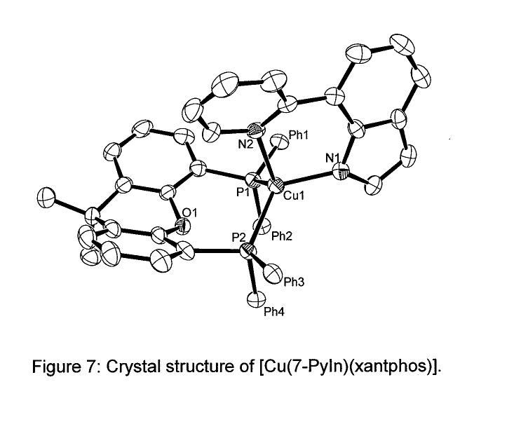

FIG. 8: Absorption and luminescence spectrum of [Cu(7-Pyln)(L′)]. L′: X=xantphos, P=(PPh₃)₂, D=dppb. (a: spectrum of solid, b: spectrum in polystyrene matrix).

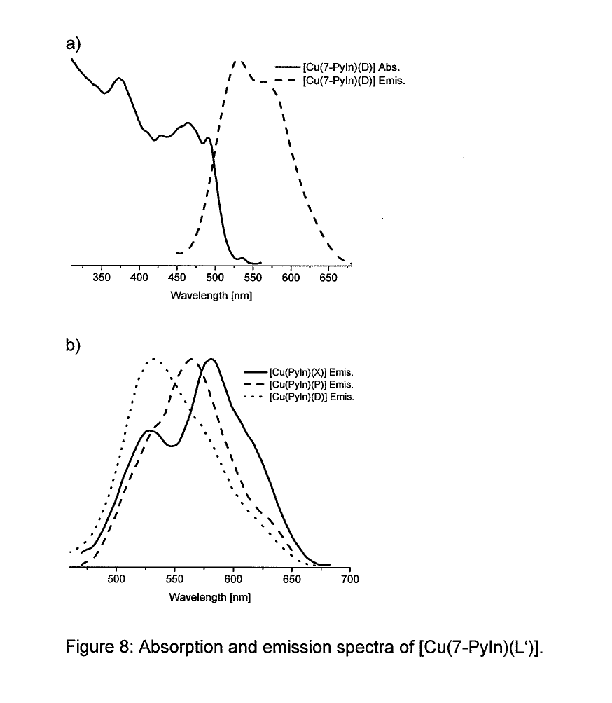

FIG. 9: Crystal structure of [Cu(8-PyQ)(dppb)].

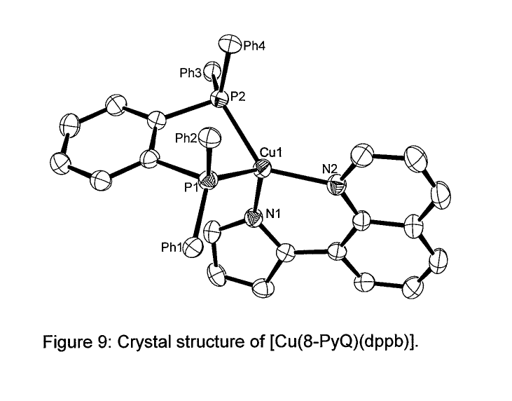

FIG. 10: Absorption and luminescence spectrum of [Cu(8-PyQ)(L′)]. L′: X=xantphos, P=(PPh₃)₂, D=dppb. (a: spectrum of solution in dichloromethane, b: spectrum of solid, c: spectrum in polystyrene matrix).

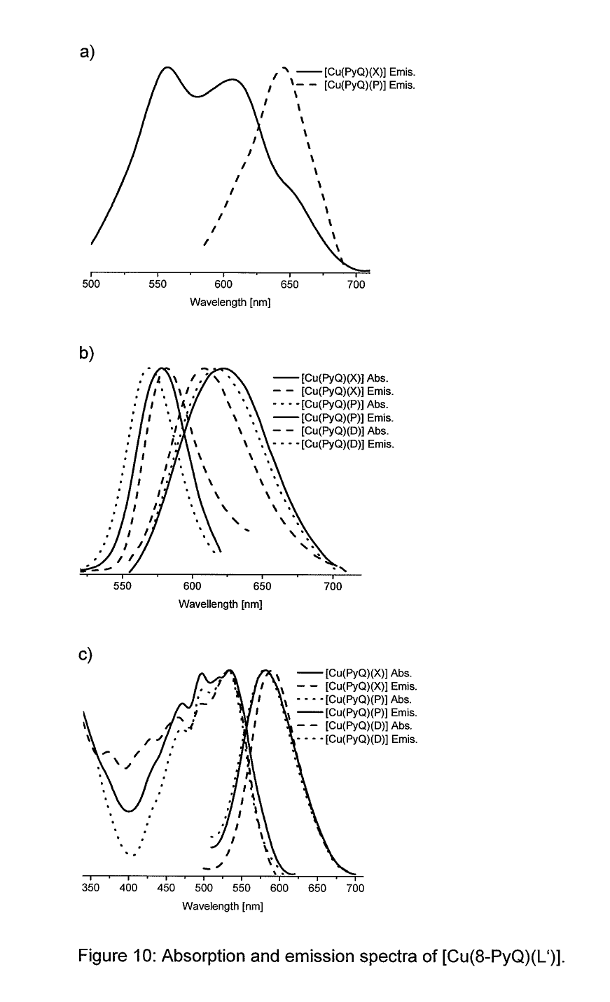

1-15. (canceled)

16. A compound of formula (1):
M(L)ₙ(L′)ₘ (1)
wherein the compound of formula (1) comprises a moiety M(L)ₙ of formula (2), wherein L is a monoanionic ligand: 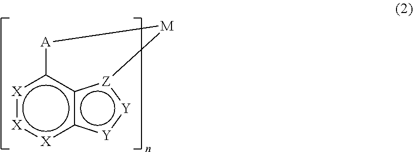
wherein
M is Cu, Ag, Au, Ru, Zn, Al, Ga, or In;
X is on each occurrence, identically or differently, CR or N;
Y is on each occurrence, identically or differently, CR or N; or precisely one group
Y is —CR═CR— or —CR═N—, so that a heteroaromatic six-membered ring is formed;
Z is on each occurrence, identically or differently, N, O, or S, with the proviso that Z is N if a group Y is —CR═CR— or —CR═N—;
A is a coordinating group coordinated to M and is optionally substituted by one or more substituents R;
R is on each occurrence, identically or differently, H, D, F, Cl, Br, I, N(R¹)₂, P(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 20 C atoms, an alkenyl or alkynyl group having 2 to 20 C atoms, or a branched or cyclic alkyl, alkoxy, or thioalkoxy group having 3 to 20 C atoms, each of which is optionally substituted by one or more substitutents R¹, wherein one or more non-adjacent CH₂ groups are optionally replaced by R¹C═CR¹, C≡C, Si(R¹)₂, C═O, NR¹, O, S, or CONR¹ and wherein one or more H atoms are optionally replaced by D, F, Cl, Br, I, or CN, an aromatic or heteroaromatic ring system having 5 to 60 aromatic ring atoms optionally substituted by one or more substitutents R¹, an aryloxy or heteroaryloxy group having 5 to 40 aromatic ring atoms optionally substituted by one or more substituents R¹, an aralkyl or heteroaralkyl group having 5 to 40 aromatic ring atoms optionally substituted by one or more substituents R¹, or a diarylamino group, diheteroarylamino group, or arylheteroaryl amino group having 10 to 40 aromatic ring atoms optionally substituted by one or more radicals R¹; and wherein two adjacent substituents R optionally define a mono- or polycyclic, aromatic or aliphatic ring system with one another;
R¹ is on each occurrence, identically or differently, H, D, F, Cl, Br, I, N(R²)₂, P(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy, or thioalkoxy group having 1 to 20 C atoms, an alkenyl or alkynyl group having 2 to 20 C atoms, or a branched or cyclic alkyl, alkoxy or thioalkoxy group having 3 to 20 C atoms optionally substituted by one or more radicals R², wherein one or more non-adjacent CH₂ groups are optionally replaced by R²C═CR², C≡C, Si(R²)₂, C═O, NR², O, S, or CONR², and wherein one or more H atoms are optionally replaced by D, F, Cl, Br, I, CN, or NO₂, an aromatic or heteroaromatic ring system having 5 to 60 aromatic ring atoms optionally substituted by one or more substituents R², an aryloxy or heteroaryloxy group having 5 to 40 aromatic ring atoms optionally substituted by one or more substituents R², an aralkyl or heteroaralkyl group having 5 to 40 aromatic ring atoms optionally substituted by one or more substituents R², or a diarylamino group, diheteroarylamino group or arylheteroarylamino group having 10 to 40 aromatic ring atoms optionally substituted by one or more substituents R²; and wherein two or more adjacent substituents R² optionally define a mono- or polycyclic, aromatic or aliphatic ring system with one another;
R² is on each occurrence, identically or differently, H, D, F, or an aliphatic, aromatic and/or heteroaromatic hydrocarbon radical having 1 to 20 C atoms, wherein one or more H atoms are optionally replaced by F; and wherein two or more substituents R² optionally define a mono- or polycyclic, aromatic or aliphatic ring system with one another;
L′ is, identically or differently on each occurrence, any desired co-ligand or is a coordinating group if L′ is linked to L via V;
n is 1, 2, or 3;
m is 0, 1, 2, 3, or 4;
wherein one or two substituents R or R¹ on L are optionally bonded to M to form a tri- or tetradentate ligand; and
wherein L is optionally linked to L′ via one or two bridging units V to form a linear tri- or tetradentate ligand.

17. The compound of claim 16, wherein the compound is uncharged.

18. The compound of claim 16, wherein M is selected from the group consisting of Cu(I), Ag(I), Au(I), Ru(II), Zn(II), Al(III), Ga(III), and In(III), preferably Cu(I).

19. The compound of claim 16, wherein M is Cu(I).

20. The compound of claim 16, wherein a maximum of one group X is N and the other groups X are CR.

21. The compound of claim 16, wherein either both groups Y are CR or one group Y is CR and the other group Y is —CR═CR—.

22. The compound of claim 16, wherein the moiety of formula (2) is selected from the group consisting of moieties of formulae (3) to (6):

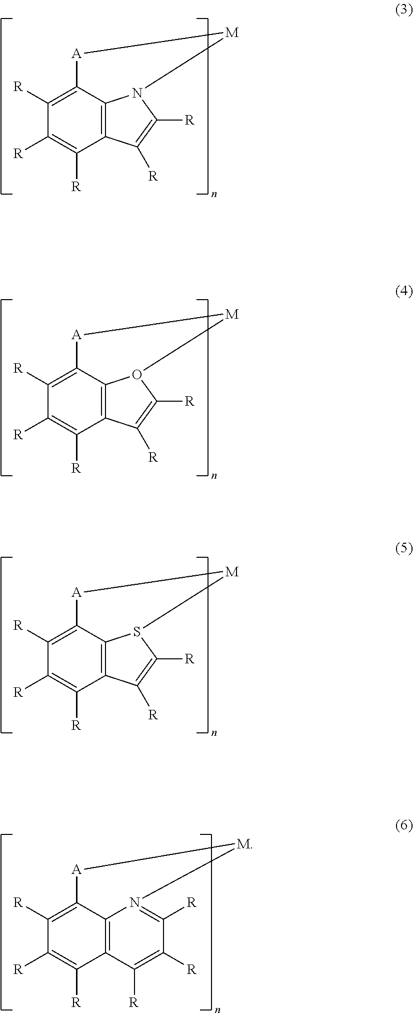

23. The compound of claim 16, wherein A is a heteroaryl group having 5 to 14 aromatic ring atoms, which is coordinated to M via a heteroatom and which is optionally substituted by one or more substituents R.

24. The compound of claim 16, wherein A is a heteroaryl group having 5 to 10 aromatic ring atoms, which is coordinated to M via a heteroatom and which is optionally substituted by one or more substituents R.

25. The compound of claim 16, wherein A coordinated to M is selected from the group consisting of the structures of formulae (7) to (57), wherein the position denoted by # in each case denotes the bond to the remainder of the ligand L and the position at which the group is coordinated to M is denoted by *: 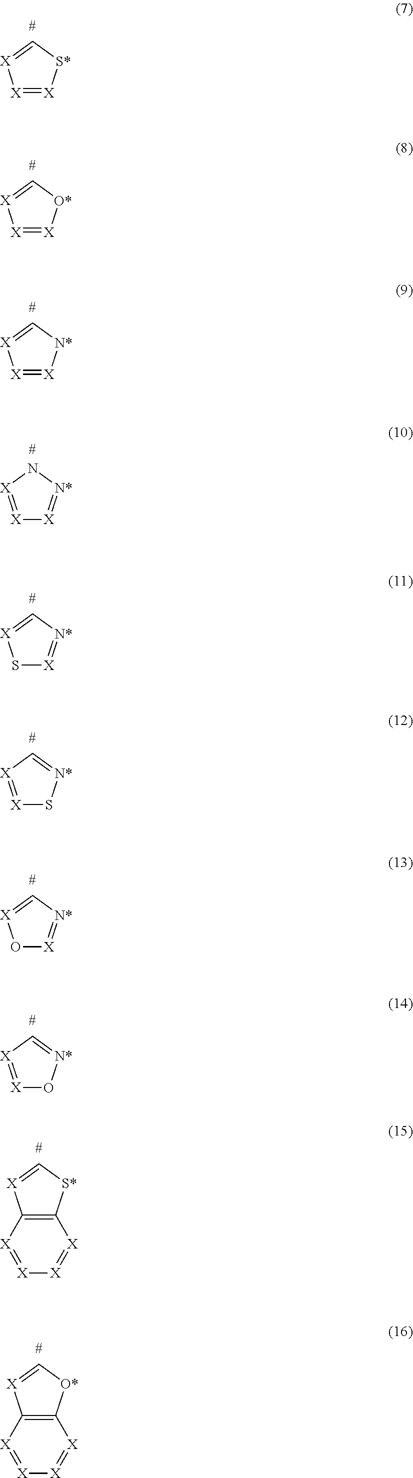 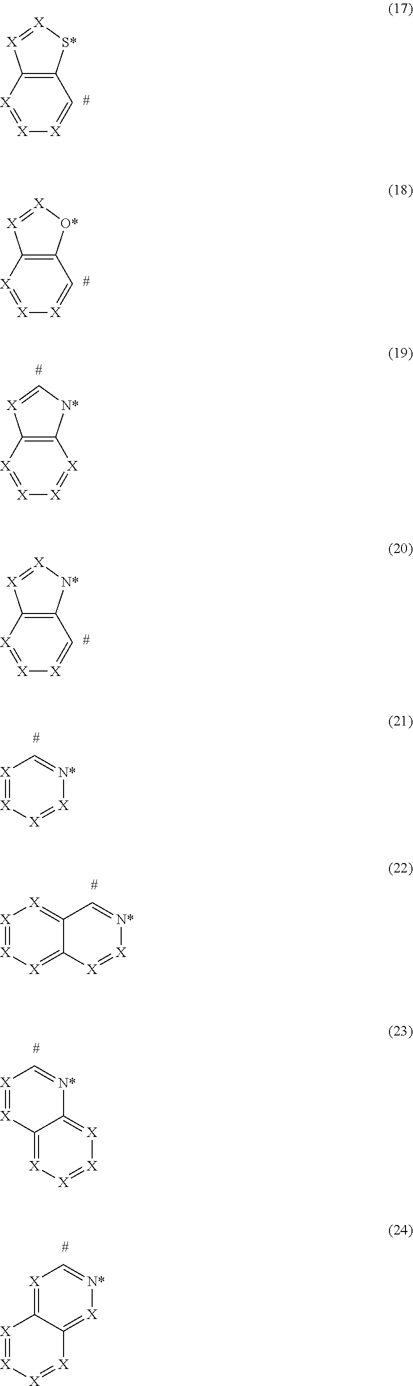 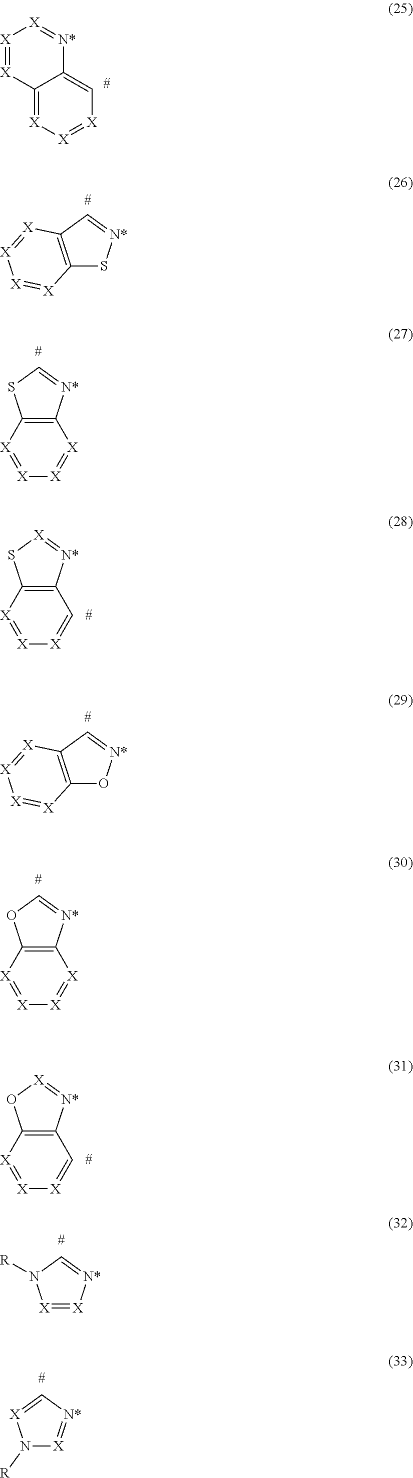 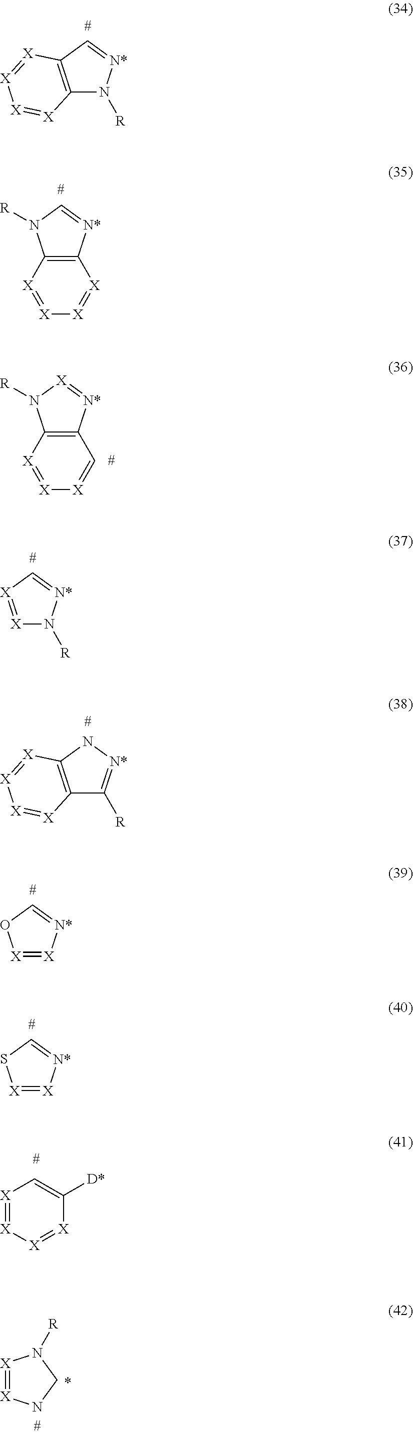 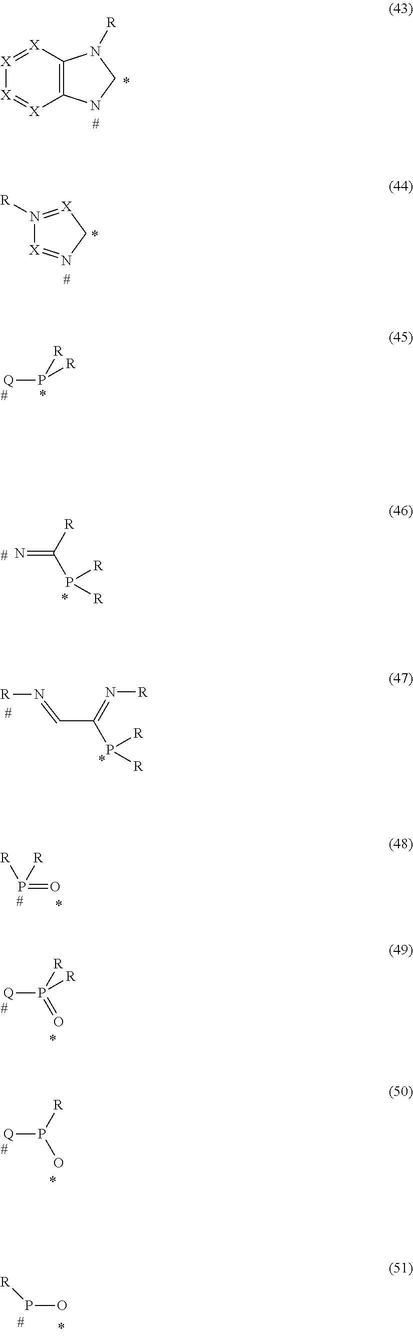 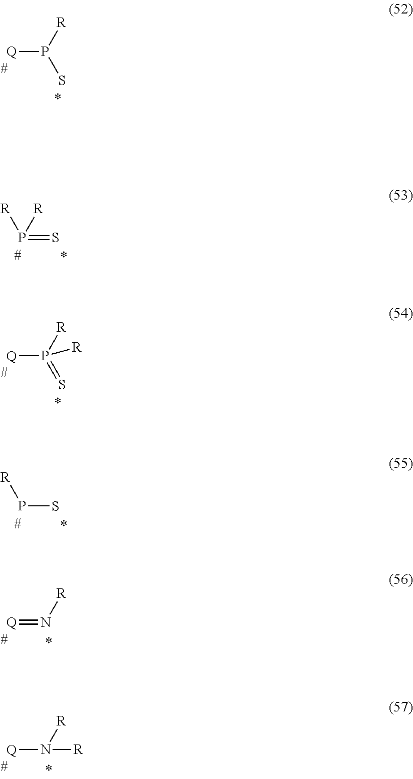
wherein
D is O⁻, S⁻, NR⁻, NR₂, PR₂, COO⁻, SO₃⁻, —C(═O)R, —CR(═NR), or —N(═CR₂); and
Q is a divalent group selected on each occurrence, identically or differently, from the group consisting of a straight-chain alkylene group having 1 to 8 C atoms, an alkenyl or alkynyl group having 2 to 8 C atoms, or a branched or cyclic alkylene group having 3 to 8 C atoms, each of which is optionally substituted by one or more substituents R¹, wherein one or more non-adjacent CH₂ groups are optionally replaced by R¹C═CR¹, C≡C, Si(R¹)₂, C═O, NR¹, O, S, BR¹, or CONR¹, a divalent aromatic or heteroaromatic ring system having 5 to 20 aromatic ring atoms optionally substituted by one or more substituents R¹, a divalent aryloxy or heteroaryloxy group having 5 to 20 aromatic ring atoms optionally substituted by one or more substituents R¹, or a divalent aralkyl or heteroaralkyl group having 5 to 20 aromatic ring atoms optionally substituted by one or more substituents R¹, or a combination of two of the above-mentioned groups.

26. The compound of claim 16, wherein the compound is selected from the group consisting of the structures of formulae (62) to (67): 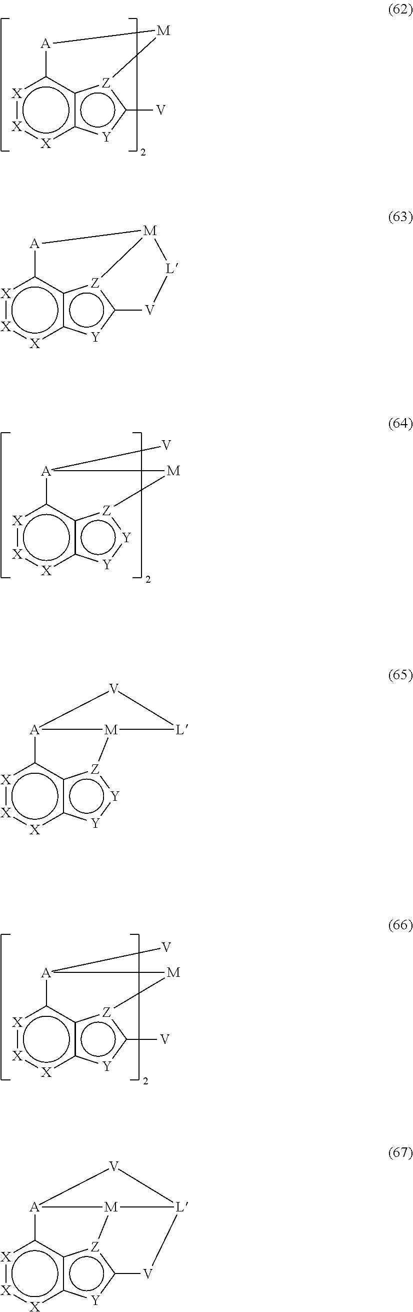
wherein
V is a single bond or a bridging unit containing 1 to 80 atoms from the third, fourth, fifth and/or sixth main group (IUPAC group 13, 14, 15 or 16) or a 3- to 6-membered homo- or heterocycle which covalently bonds the part-ligands L to one another or L to L′ to one another.

27. The compound of claim 16, wherein L′ is selected from the group consisting of carbon monoxide, nitrogen monoxide, alkyl cyanides, aryl cyanides, alkyl isocyanides, aryl isocyanides, amines, phosphines, phosphites, arsines, stibines, nitrogen-containing heterocycles, oxygen-containing heterocycles, sulfur-containing heterocycles, ethers, thioethers, carbenes, hydride, deuteride, F⁻, Cl⁻, Br⁻, I⁻, alkylacetylides, arylacetylides, cyanide, cyanate, isocyanate, thiocyanate, isothiocyanate, aliphatic alcoholates, aromatic alcoholates, aliphatic thioalcoholates, aromatic thioalcoholates, amides, carboxylates, anionic, nitrogen-containing heterocycles, diamines, imines, heterocycles containing two nitrogen atoms, diphosphines, 1,3-diketonates derived from 1,3-diketones, 3-ketonates derived from 3-ketoesters, carboxylates derived from aminocarboxylic acids, salicyliminates derived from salicylimines, dialcoholates derived from dialcohols and dithiolates derived from dithioles.

28. A process for preparing the compound of claim 16 comprising reacting a free ligand L, optionally in deprotonated form, and optionally further ligands L′, with a metal salt or metal complex.

29. A formulation comprising at least one compound of claim 16 and at least one solvent.

30. An electronic device comprising one or more compounds of claim 16.

31. The electronic device of claim 30, wherein the device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells, and organic laser diodes

32. The electronic device of claim 30, wherein the device is an organic electroluminescent device and wherein the one or more compounds of claim 16 is employed as an emitting compound and/or as a matrix material in one or more emitting layers.
